(19) United States
(12) Patent Application Publication
(10) Pub. No.: US 2026/0088100 A1
(43) Pub. Date: Mar. 26, 2026

(54) MEMORY DEVICE AND METHOD OF OPERATING THE SAME

(71) Applicant: SK hynix Inc., Gyeonggi-do (KR)

(72) Inventor: Hyeok Jun CHOI, Gyeonggi-do (KR)

(21) Appl. No.: 19/189,147

(22) Filed: Apr. 24, 2025

(30) Foreign Application Priority Data
Sep. 26, 2024 (KR) 10-2024-0130806

(51) Int. Cl. G11C 16/24; G11C 16/32; G11C 16/34

(52) U.S. Cl. CPC G11C 16/24; G11C 16/32; G11C 16/3459

(57) ABSTRACT

A memory device may include a peripheral circuit and a control circuit. The peripheral circuit performs a program operation on memory cells, verifies the memory cells based on a target voltage and a pre-target voltage, and applies bit line voltages to bit lines. The control circuit controls the peripheral circuit to determine the memory cells to be initial cells programmed, adjacent cells programmed, and complete cells programmed, adjusts timings at which the bit line voltages are to be applied to bit lines connected to the initial cells programmed, the adjacent cells programmed, and the complete cells programmed. In performing these operations, the control circuit controls the peripheral circuit to adjust the timing of a voltage to be applied to a bit line connected to the adjacent cells programmed depending on a number of at least one of the initial cells programmed, the adjacent cells programmed, or the complete cells programmed.

### CROSS-REFERENCE TO RELATED APPLICATION

The present application claims priority under 35 U.S.C. § 119(a) to Korean patent application number 10-2024-0130806, filed on Sep. 26, 2024, the entire disclosure of which is incorporated by reference herein.

### BACKGROUND

### 1. Technical Field

Various embodiments of the present disclosure relate to a memory device and a method of operating the memory device, and more particularly to a memory device and a method of operating the memory device, which perform a program operation.

### 2. Related Art

A memory device may include a memory cell array in which data is stored, and a peripheral circuit which performs a program operation, a read operation, or an erase operation. The memory cell array may include memory blocks. Each of the memory blocks may include a plurality of memory cells. Because memory cells have different electrical characteristics, the times during which the memory cells are programmed may be different from each other.

The peripheral circuit may include a control circuit which controls the operation of the memory device in response to a command transmitted from an external controller, and circuits which perform a program operation, an erase operation or a read operation under the control of the control circuit.

When a program operation is performed on a selected memory block, threshold voltage distributions of memory cells included in the selected memory block may be widened due to a difference of the program speeds of the memory cells. For example, when a program voltage is applied to a selected word line, the threshold voltages of memory cells connected to the selected word line may be increased due to the program voltage. The threshold voltages increase because the programming process injects electrons onto the floating gates of the memory cells. This creates an accumulation of negative charges in the floating gates that requires higher voltages to overcome in order to turn the memory cell transistors on, which raises the threshold voltages of the memory cells.

The program speed of the memory cells may be directly proportional to the threshold voltages of memory cells. For example, the threshold voltages of memory cells having a relatively high program speed may increase at a faster rate than those of memory cells having a relatively low program speed. Thus, the threshold voltage distributions thereof may be widened. Because the threshold voltage distributions are widened, the number of error bits occurring in a read operation may increase, thus deteriorating the reliability of the memory device.

### SUMMARY

Various embodiments of the present disclosure are directed to a memory device and a method of operating the memory device, which can improve the threshold voltage distributions of memory cells.

An embodiment of the present disclosure may provide a memory device. The memory device may include one or more memory cells, a peripheral circuit configured to perform a program operation on the memory cells, verify the memory cells based on a target voltage and a pre-target voltage less than the target voltage, and apply voltages to bit lines connected to the memory cells, and a control circuit coupled to the peripheral circuit, and configured to determine memory cells to be initial cells programmed, adjacent cells programmed, and complete cells programmed depending on a result of a verification performed on the memory cells, and adjust timings at which bit line voltages are to be applied to bit lines connected to the initial cells programmed, the adjacent cells programmed, and the complete cells programmed, wherein adjusting the timings of the bit line voltages includes controlling the peripheral circuit to adjust a timing of at least one bit line voltage to be applied to a bit line connected to one of the adjacent cells programmed among the bit line voltages, depending on a number of at least one of the initial cells programmed, the adjacent cells programmed, or the complete cells programmed.

An embodiment of the present disclosure may provide a method of operating a memory device. The method may include classifying memory cells as initial cells programmed, adjacent cells programmed, or complete cells programmed depending on a result of a verification performed on the memory cells during a program operation, applying a program-enable voltage to a first bit line corresponding to the initial cells programmed, selectively applying a second program-inhibit voltage and the program-enable voltage to a second bit line corresponding to the adjacent cells programmed, and applying a first program-inhibit voltage to a third bit line corresponding to the complete cells programmed, applying a program voltage to a word line connected to the memory cells, and adjusting a time during which the second program-inhibit voltage is applied to the second bit line depending on a number of initial cells programmed and the adjacent cells programmed.

### BRIEF DESCRIPTION OF THE DRAWINGS

FIG. 1 is a diagram illustrating a memory device according to an embodiment of the present disclosure.

FIG. 2 is a diagram illustrating the arrangement of a memory cell array and a peripheral circuit according to an embodiment of the present disclosure.

FIG. 3 is a perspective view illustrating a memory block according to an embodiment of the present disclosure.

FIG. 4 is a circuit diagram illustrating a memory block according to an embodiment of the present disclosure.

FIG. 5 is a diagram illustrating the states of memory cells depending on threshold voltages according to an embodiment of the present disclosure.

FIG. 6 is a diagram illustrating voltages applied to a selected memory block during a program operation according to an embodiment of the present disclosure.

FIG. 7 is a flowchart illustrating a program operation according to a first embodiment of the present disclosure.

FIG. 8 is a diagram illustrating a verify operation according to an embodiment of the present disclosure.

FIGS. 9A to 9D are diagrams illustrating program operations according to a first embodiment of the present disclosure.

FIG. 10 is a flowchart illustrating a program operation according to a second embodiment of the present disclosure.

FIGS. 11A to 11C and 12A to 12C are diagrams illustrating program operations according to a second embodiment of the present disclosure.

FIGS. 13A to 13D are diagrams illustrating the threshold voltages of memory cells that are successively increased during a program operation according to the present disclosure.

FIG. 14 is a diagram illustrating a memory card system to which a memory device according to an embodiment of the present disclosure is applied.

FIG. 15 is a diagram illustrating a solid state drive (SSD) system to which a memory device according to an embodiment of the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, although the terms “first” and “second” may be used herein to describe various elements, these elements should not be limited by these terms. The terms are used to distinguish one element from other elements.

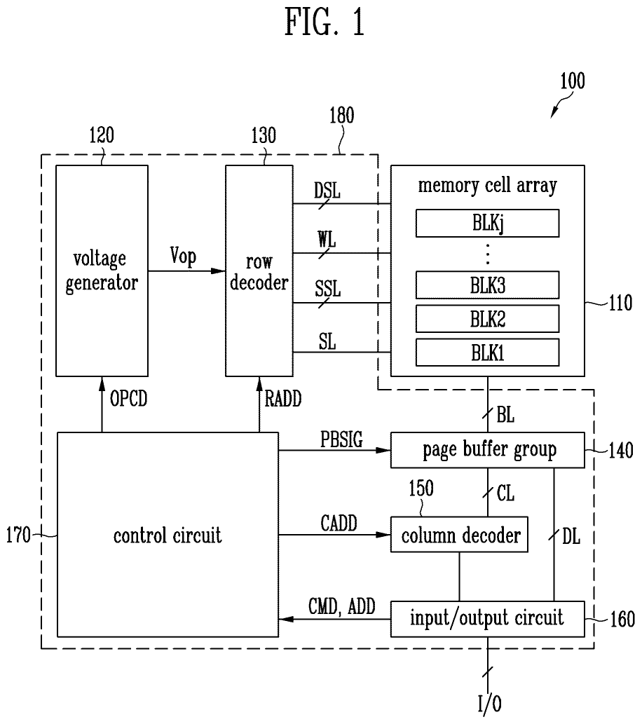

FIG. 1 is a diagram illustrating a memory device 100 according to an embodiment of the present disclosure.

Referring to FIG. 1, the memory device 100 may include a memory cell array 110 in which data is stored, and a peripheral circuit 180 which performs a program operation, a read operation or an erase operation on the memory cell array 110.

The memory cell array 110 may include first to j-th memory blocks BLK1 to BLKj in which data is stored. Each of the first to j-th memory blocks BLK1 to BLKj may include a plurality of memory cells, which may be implemented in a two-dimensional (2D) structure in which the memory cells are arranged horizontally on a substrate or in a three-dimensional (3D) structure in which the memory cells are stacked vertically on a substrate. Each of the first to j-th memory blocks BLK1 to BLKj according to the present embodiment may be formed in a 3D structure. Drain select lines DSL, word lines WL, source select lines SSL, and a source line SL may be connected to each of the first to j-th memory blocks BLK1 to BLKj.

The peripheral circuit 180 may include a voltage generator 120, a row decoder 130, a page buffer group 140, a column decoder 150, an input and output (input/output) circuit 160, and a control circuit 170.

The voltage generator 120 may generate and output operating voltages Vop required for various operations in response to an operation code OPCD. For example, the voltage generator 120 may generate and output a program voltage, a verify voltage, a read voltage, a pass voltage, an erase voltage, a compensation voltage, etc. The voltage generator 120 may adjust respective levels, output times or blocking times of the operating voltages Vop in response to the operation code OPCD.

The row decoder 130 may select one memory block from among the first to j-th memory blocks BLK1 to BLKj included in the memory cell array 110 according to a row address RADD, and may transmit the operating voltages Vop to the selected memory block.

The page buffer group 140 may be connected to the memory cell array 110 through bit lines BL. For example, the page buffer group 140 may include a plurality of page buffers connected to the bit lines BL, respectively. The page buffers may be simultaneously operated in response to page buffer control signals PBSIG, and may temporarily store data during a program or read operation. For this operation, each of the page buffers may include a plurality of latches in which data is temporarily stored. The number of latches may vary depending on a program method. For example, the page buffers may be designed differently depending on the number of bits that can be stored in one memory cell, and may be designed differently depending on the number of verify voltages used in a verify operation.

The column decoder 150 may transfer data DATA between the input/output circuit 160 and the page buffer group 140 according to a column address CADD.

The input/output circuit 160 may be connected to a controller through input/output lines (IO). The input/output circuit 160 may receive or output a command CMD, an address ADD, and data DATA through the input/output lines (IO) from an external device such as a controller or a memory controller. For example, the input/output circuit 160 may transmit the command CMD and the address ADD, received through the input/output lines (IO), to the control circuit 170, and may transmit the data DATA, received through the input/output lines (IO), to the column decoder 150. The input/output circuit 160 may output the data DATA, received from the column decoder 150, to the external device through the input/output lines (IO).

The control circuit 170 may output the operation code OPCD, the row address RADD, the page buffer control signals PBSIG, and the column address CADD in response to the command CMD and the address ADD. For example, the control circuit 170 may include software which executes a program operation, a read operation or an erase operation in response to the command CMD and the address ADD, and hardware which outputs the operation code OPCD, the row address RADD, the page buffer control signals PBSIG, and the column address CADD under the control of the software.

The control circuit 170 may be set to perform a program operation according to a single-level cell scheme or a multi-level cell scheme. The single-level cell scheme is a scheme for programming 1 bit of data to one memory cell. When the program operation is performed according to the single-level cell scheme, each memory cell may enter an erase state or a program state. The multi-level cell scheme is a scheme for programming 2 or more bits of data to one memory cell. For example, the 2 or more bits of data may be programmed into a memory cell based on different levels of electrical charge in a floating gate. When the program operation is performed according to the multi-level cell scheme, each memory cell may enter the erase state or any one of a plurality of program states. For example, when 3 bits of data are programmed to one memory cell, the memory cell may enter the erase state or any one of seven different program states.

Because memory cells have different electrical characteristics, program speeds thereof may also be different from each other. For example, a memory cell having a relatively high program speed becomes a fast cell, and a memory cell having a relatively low program speed becomes a slow cell. During a program operation, the threshold voltage of the fast cell may be increased more rapidly than the slow cell. Therefore, even if the same program voltage is applied to the fast cell and the slow cell, the threshold voltages of the fast cell and the slow cell may be different from each other and may increase at different rates. For example, the fast cells generally have higher threshold voltages than slow cells. As the difference between the threshold voltages increases, the width of threshold voltage distributions of the memory cells increases.

Based on the result of verification on the memory cells, the control circuit 170 according to the present embodiment may determine the memory cells to be initial cells programmed, adjacent cells programmed, or complete cells programmed. The control circuit 170 may control the peripheral circuit 180 to control voltages to be applied to bit lines connected to the initial cells programmed, the adjacent cells programmed, or the complete cells programmed and to adjust the times during which the voltages are applied to the bit lines depending on the number of initial cells programmed and the number of adjacent cells programmed.

In order to decrease the width of threshold voltage distributions, the control circuit 170 according to the present embodiment may determine the states of memory cells during a program operation on the selected memory block, and may control the page buffer group 140 so that the voltages to be applied to the bit lines are adjusted based on the result of determination.

In order to decrease the width of the threshold voltage distributions, the control circuit 170 according to the present embodiment may control the page buffer group 140 so that the voltages to be applied to the bit lines are adjusted depending on the number of incomplete cells that has failed the verify operation or the number of pass cells that has passed the verify operation during a program operation on the selected memory block. For example, the control circuit 170 may compare a preset reference number of cells with the number of incomplete cells, and may adjust the voltages to be applied to the bit lines based on the result of the comparison. The preset reference number may be a value stored in the control circuit, and may be changed according to the memory device.

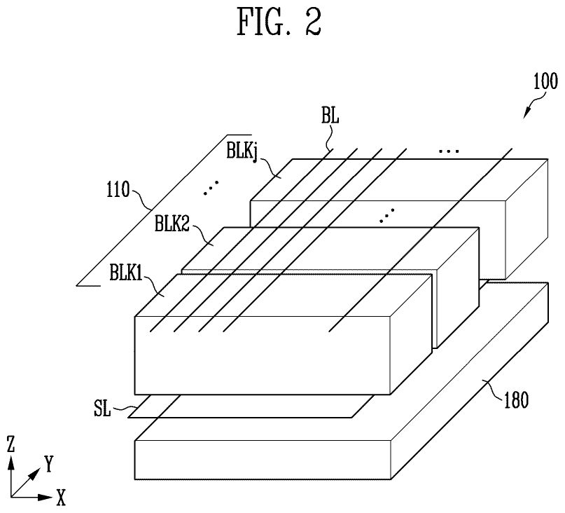

FIG. 2 is a diagram illustrating the arrangement of the memory cell array 110 and the peripheral circuit 180 according to an embodiment.

Referring to FIG. 2, the peripheral circuit 180 may be disposed on a substrate, and the memory cell array 110 may be disposed over the peripheral circuit 180. The memory cell array 110 may include first to j-th memory blocks BLK1 to BLKj. Bit lines BL may be disposed on the first to j-th memory blocks BLK1 to BLKj, and a source line SL may be disposed under the first to j-th memory blocks BLK1 to BLKj. Unlike the structure illustrated in FIG. 2, the bit lines BL may be disposed under the first to j-th memory blocks BLK1 to BLKj, and the source line SL may be disposed on the first to j-th memory blocks BLK1 to BLKj.

The plurality of bit lines BL may be arranged to be spaced apart from each other along an X direction, and may extend along a Y direction. The first to j-th memory blocks BLK1 to BLKj may be arranged to be spaced apart from each other along the Y direction. The source line SL may be connected in common to the first to j-th memory blocks BLK1 to BLKj. The first to j-th memory blocks BLK1 to BLKj may be configured in the same manner. Among the memory blocks, any one memory block will be described in detail below.

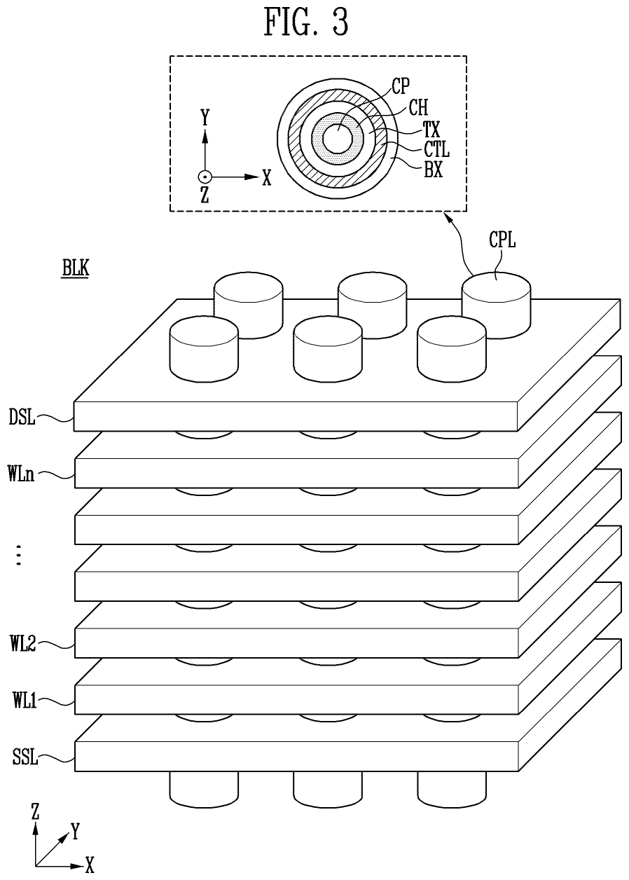

FIG. 3 is a perspective view illustrating a memory block BLK, which, for example, may be representative of the first to j-th memory blocks BLK1 to BLKj.

Referring to FIG. 3, a portion of the memory block BLK is illustrated. A source select line SSL, first to n-th word lines WL1 to WLn, and a drain select line DSL, which are included in the memory block BLK, may be stacked to be spaced apart from each other along a Z direction. The source select line SSL, the first to n-th word lines WL1 to WLn, and the drain select line DSL may be formed of the same conductive material. For example, each of the source select line SSL, the first to n-th word lines WL1 to WLn, and the drain select line DSL may be formed of a metal material such as tungsten (W), molybdenum (Mo), cobalt (Co), or nickel (Ni), or a semiconductor material such as silicon (Si) or polysilicon (Poly-Si), but the material is not limited thereto.

Cell plugs CPL may penetrate the source select line SSL, the first to n-th word lines WL1 to WLn, and the drain select line DSL. Each of the cell plugs CPL may include a core pillar CP, a channel layer CH, a tunnel isolation layer TX, a charge trap layer CTL, and a blocking layer BX coupled between one of the bit lines BL and the select line SL. The core pillar CP may have the shape of a cylinder, a rectangular pillar, or a polygonal pillar, and may be formed of an insulating material or a conductive material. The channel layer CH may enclose the surface of the core pillar CP, and may be formed of polysilicon. The tunnel isolation layer TX may enclose the surface of the channel layer CH, and may be formed of an oxide layer. The charge trap layer CTL may enclose the surface of the tunnel isolation layer TX, and may be formed of a nitride layer. The blocking layer BX may enclose the surface of the charge trap layer CTL, and may be formed of an oxide layer.

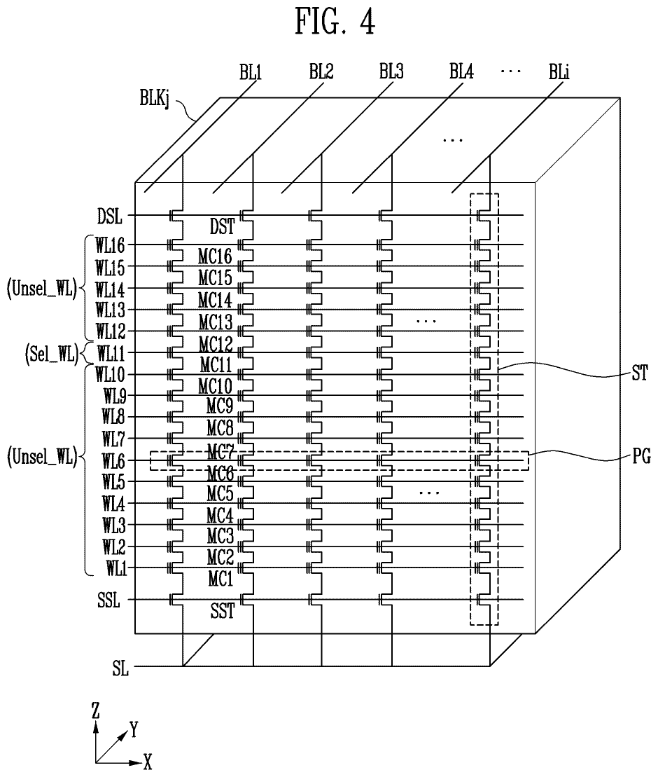

FIG. 4 is a circuit diagram illustrating a memory block BLK which may be representative of the memory blocks shown in FIG. 2.

Referring to FIG. 4, the memory block BLK (e.g., BLKj) may include cell strings ST disposed between the source line SL and respective ones of first to i-th bit lines BL1 to BLi. The cell strings ST may be arranged to be spaced apart from each other along X and Y directions, and may extend along a Z direction. The first to i-th bit lines BL1 to BLi may be arranged to be spaced apart from each other along the X direction, and each of the first to i-th bit lines BL1 to BLi may extend along the Y direction. Each of the cell strings ST may include a source select transistor SST, first to sixteenth memory cells MC1 to MC16, and a drain select transistor DST. The first to sixteenth memory cells MC1 to MC16 may be connected between the source select transistor SST and the drain select transistor DST. The numbers of source select transistors SST, first to sixteenth memory cells M1 to M16, and drain select transistors DST, illustrated in FIG. 4, may vary depending on the memory device.

Gates of source select transistors SST included in different cell strings ST may be connected to a source select line SSL, gates of the first to sixteenth memory cells MC1 to MC16 may be connected to first to sixteenth word lines WL1 to WL16, respectively, and gates of drain select transistors DST may be connected to a drain select line DSL. The source select line SSL may be connected in common to the source select transistors SST arranged along the X and Y directions. Alternatively, the memory block may include a plurality of source select lines SSL. For example, a source select line SSL may be connected in common to the source select transistors SST arranged in the X direction, and another source select line SSL may be connected in common to the source select transistors SST arranged in the Y direction. The different source select lines SSL may be separated from each other.

Each of the first to sixteenth word lines WL1 to WL16 may be connected in common to the memory cells arranged along the X and Y directions. For example, the first memory cells MC1 arranged along the X and Y directions may be connected in common to the first word line WL1, and the second memory cells MC2 arranged along the X and Y directions may be connected in common to the second word line WL2. The drain select line DSL may be connected in common to the drain select transistors DST arranged in the X direction. Different drain select lines DSL may be connected to the drain select transistors DST arranged in the Y direction.

A group of memory cells connected to the same word line may be a page (PG). In the example shown, the group of memory cells MC6 connected to word line WL6 may correspond to one page PG. Thus, each memory block BLK may include a plurality of pages equal in number to the number of word lines provided for the memory block BLK. A program or read operation may be performed on a page (PG) basis. For example, a group of memory cells connected to a selected word line among memory cells in the cell strings ST connected to a drain select line DSL, selected from among the drain select lines DSL, may be a selected page. The selected page may be a page including program target memory cells during a program operation. That is, the selected page may be determined by the drain select line DSL and the corresponding word line.

Because the program operation on the memory block BLK is performed on a page basis, a word line connected to the selected page may be referred to as a selected word line Sel_WL, and word lines connected to the remaining pages may be referred to as unselected word lines Unsel_WL. For example, when the eleventh word line WL11 is the selected word line Sel_WL, the first to tenth word lines WL1 to WL10 and twelfth to sixteenth word lines WL12 to WL16 may be the unselected word lines Unsel_WL within the memory block BLKj.

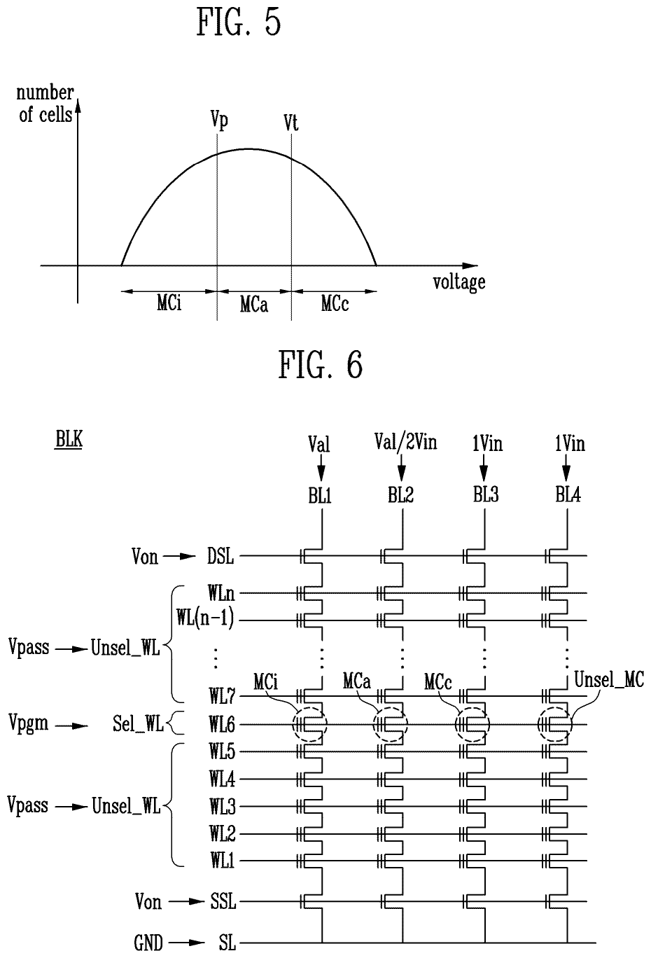

FIG. 5 is a diagram illustrating the states of memory cells depending on threshold voltages according to one embodiment of the present disclosure. In the graph of FIG. 5, the horizontal axis denotes voltages, and the vertical axis denotes the number of memory cells (e.g., number of cells).

Referring to FIG. 5, during a program operation, a selected memory cell may be any one of three types: an initial cell programmed MCi, an adjacent cell programmed MCa, and a complete cell programmed MCc. The type of memory cell may depend on the magnitude of its threshold voltage. For example, a complete cell programmed MCc may be a cell having a threshold voltage which is increased to a target voltage Vt or greater. An adjacent cell programmed MCa may be a cell having a threshold voltage which is less than the target voltage Vt and greater than a pre-target voltage Vp. An initial cell programmed MCi may be a cell having a threshold voltage which is less than the pre-target voltage Vp.

The target voltage Vt may be a reference voltage for determining whether each memory cell has been programmed to a target program state. The pre-target voltage Vp may be set to a voltage lower than the target voltage Vt.

During a program operation in the multi-level cell scheme, the memory cells are programmed to various states, and thus a plurality of target voltages Vt may be set. When the plurality of target voltages Vt are set, a plurality of pre-target voltages Vp corresponding to respective ones of the plurality of target voltages Vt may be set. When the plurality of pre-target voltages Vp are set, the pre-target voltages Vp may be set to be less than the target voltages Vt corresponding to the pre-target voltages Vp and greater than the highest threshold voltage in a threshold voltage distribution in a state less than the corresponding target voltages Vt.

In the present embodiment, the states of the memory cells may correspond to the types of memory cells previously mentioned, e.g., the states of the memory cells may be classified as initial cells programmed MCi, adjacent cells programmed MCa or complete cells programmed MCc according to the threshold voltages of the memory cells. Each adjacent cell programmed MCa may be a memory cell having a threshold voltage which is less than a target voltage Vt, but which is increased during a program operation that closer to the target voltage Vt. Therefore, in the present embodiment, the voltage of the bit line corresponding to an adjacent cell programmed MCa is adjusted.

FIG. 6 is a diagram illustrating voltages applied to a selected memory block during a program operation according to the present disclosure.

Referring to FIG. 6, during a program operation on a memory block BLK, a program voltage Vpgm may be applied to a selected word line Sel_WL, and a pass voltage Vpass may be applied to unselected word lines Unsel_WL. The program voltage Vpgm has a level greater than 0 V so as to increase the threshold voltages of selected memory cells, and may be step-wise increased while the program operation is being performed. The pass voltage Vpass may be a voltage for forming a channel in a string, and may be set to a level at which memory cells connected to the unselected word lines Unsel_WL can be turned on.

A ground voltage GND may be applied to a source line SL, and a turn-on voltage Von may be applied to a source select line SSL and a drain select line DSL. The turn-on voltage Von may be set to a level at which source select transistors and drain select transistors can be turned on.

A voltage selected from among a program-enable voltage Val, a first program-inhibit voltage 1Vin, and a second program-inhibit voltage 2Vin may be applied to each of first to fourth bit lines BL1 to BL4 depending on the states of the memory cells.

In the illustrated example of FIG. 6, a sixth word line WL6 is a selected word line Sel_WL, a memory cell corresponding to a first bit line BL1, from among memory cells connected to the selected word line Sel_WL, is an initial cell programmed MCi, a memory cell corresponding to a second bit line BL2 is an adjacent cell programmed MCa, a memory cell corresponding to a third bit line BL3 is a complete cell programmed MCc, and a memory cell corresponding to a fourth bit line BL4 is an unselected cell Unsel_MC.

Because a voltage difference between the threshold voltage of the initial cell programmed MCi and a target voltage is greater than a voltage difference between the threshold voltage of the adjacent cell programmed MCa and the target voltage, the program-enable voltage Val (that is the lowest voltage among voltages applied to the bit lines) may be applied to the first bit line BL1 corresponding to the initial cell programmed MCi. The first program-inhibit voltage 1Vin (that is the highest voltage among the voltages applied to the bit lines during the program operation) may be applied to the third bit line BL3 corresponding to the complete cell programmed MCc and the fourth bit line BL4 corresponding to the unselected memory cell Unsel_MC. The program-inhibit voltage 1Vin may be a voltage that prevents memory cells (e.g., complete cells programmed and unselected memory cells) from being programmed during the program operation performed on the selected memory block. The program-inhibit voltage may also prevent the threshold voltages of these memory cells from increasing during the program operation.

At least one of the program-enable voltage Val and the second program-inhibit voltage 2Vin may be selectively applied to the second bit line BL2 connected to a string including the adjacent cell programmed MCa. For example, the program-enable voltage Val and the second program-inhibit voltage 2Vin may be applied to the second bit line BL2 during set times, respectively. For example, after the program-enable voltage Val is applied to the second bit line BL2 during a set time, the second program-inhibit voltage 2Vin may be applied to the second bit line BL2 during a subsequent set time. Alternatively, after the second program-inhibit voltage 2Vin is applied to the second bit line BL2 during a set time, the program-enable voltage Val may be applied to the second bit line BL2 during a subsequent set time. The time during which the program-enable voltage Val is applied to the second bit line BL2 and the time during which the second program-inhibit voltage 2Vin is applied to the second bit line BL2 may be changed.

During the program operation, the speed of programming of the adjacent cell programmed MCa may be adjusted by adjusting the times during which the program-enable voltage Val and the second program-inhibit voltage 2Vin are applied to the second bit line BL2 connected to a string including the adjacent cell programmed MCa. Therefore, because the speed at which the threshold voltage of the adjacent cell programmed MCa increases may be adjusted, the width of the threshold voltage distribution of memory cells may be decreased.

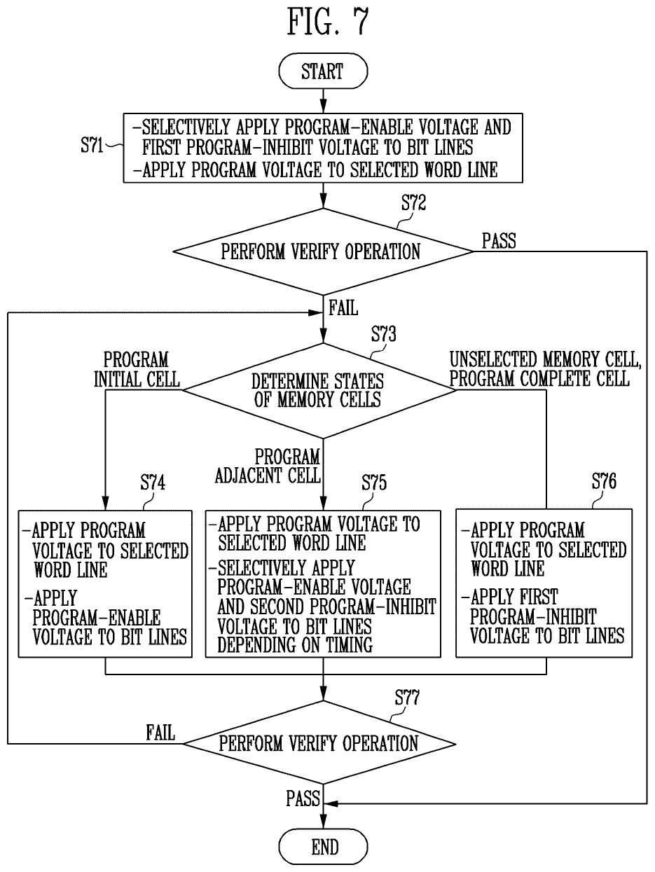

FIG. 7 is a flowchart illustrating a program operation according to a first embodiment of the present disclosure. The program operation may be explained with reference to FIGS. 5 and 6.

Referring to FIG. 7, at S71, when a program operation on a selected memory block starts, a program-enable voltage Val and a first program-inhibit voltage 1Vin may be selectively applied to bit lines connected to the selected memory block, and a program voltage Vpgm may be applied to a selected word line Sel_WL, among word lines connected to the selected memory block. The selected word line Sel_WL may be a word line connected to a selected page.

The program-enable voltage Val may be a voltage for decreasing the channel voltages of strings including selected memory cells, and may be applied to selected bit lines. The first program-inhibit voltage 1Vin may be a voltage for increasing the channel voltages of strings including unselected memory cells, and may be applied to unselected bit lines. The selected bit lines may be connected to selected strings including the selected memory cells, and the unselected bit lines may be connected to unselected strings including the unselected memory cells.

At S71, a pass voltage Vpass may be applied to unselected word lines among the word lines connected to the selected memory block. The pass voltage Vpass may be a voltage for forming channels in the unselected strings by turning on the unselected memory cells.

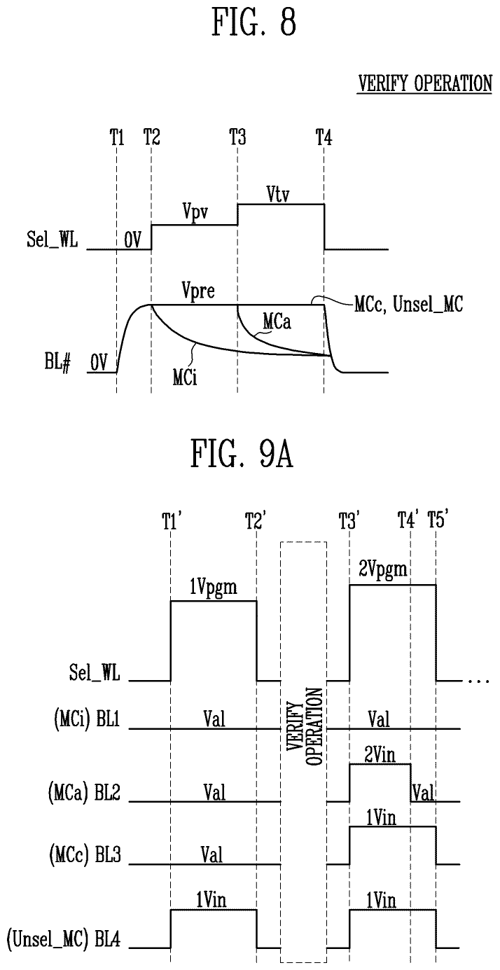

After the program voltage is applied to the selected word line Sel_WL during a certain time, a verify operation may be performed on the selected memory cells at S72. During the verify operation, a pre-verify operation using a pre-verify voltage and a target verify operation using a target verify voltage may be sequentially performed. The pre-verify voltage may be applied to the selected word line Sel_WL so as to detect memory cells having threshold voltages greater than a pre-target voltage Vp. The target verify voltage may be applied to the selected word line Sel_WL so as to detect memory cells having threshold voltages higher than the target voltage Vt. The pre-target voltage and the target voltage may be used as a basis for classifying the states of memory cells coupled to the selected word line Sel_WL, and have been described above with reference to FIG. 5. Thus, detailed description of the pre-target voltage and the target voltage will be omitted. After the pre-verify operation using the pre-verify voltage is performed at S72, the target verify operation using the target verify voltage may be performed. A detailed verify operation will be described later with reference to FIG. 8.

When both the pre-verify operation and the target verify operation have passed at S72, the program operation performed on the selected page is terminated.

When the target verify operation has failed regardless of the result of the pre-verify operation at S72, an operation of determining the states of the memory cells included in the selected page may be performed at S73.

At S73, the states of the memory cells may be determined based on the result of the verify operation performed at S72. For example, the states of the memory cells may be determined depending on the results of the pre-verify operation and the target verify operation that are sequentially performed at S72.

Depending on the result of the pre-verify operation, memory cells having threshold voltages less than the pre-target voltage and memory cells having threshold voltages greater than the pre-target voltage may be detected. Depending on the result of the target verify operation, memory cells having threshold voltages less than the target voltage and memory cells having threshold voltages greater than the target voltage may be detected.

The memory cells having threshold voltages less than the pre-target voltage may be classified as initial cells programmed MCi. The memory cells having threshold voltages that are greater than the pre-target voltage and less than the target voltage may be classified as adjacent cells programmed MCa. The memory cells having threshold voltages greater than the target voltage may be classified as complete cells programmed MCc.

The memory cells determined to be initial cells programmed MCi may be programmed according to the method corresponding to S74, The memory cells determined to be adjacent cells programmed MCa may be programmed according to the method corresponding to S75. The memory cells determined to be complete cells programmed MCc and the unselected memory cells Unsel_MC may be prevented from being programmed at S76. When the states of the memory cells are determined at S73, S74, S75 and S76 may be simultaneously performed.

At S74, the program voltage Vpgm may be reset to a voltage increased by a step voltage, and the reset program voltage may be applied to the selected word line. For example, a program voltage that becomes greater than the program voltage used in a previous program loop by the step voltage may be used. The step voltage may be a voltage difference by which the program voltage is increased in an incremental step pulse programming (ISPP) scheme, and may be preset in the memory device. The program-enable voltage Val may be applied to bit lines (e.g., BL1) of memory cells determined to be initial cells programmed MCi while the program voltage Vpgm is applied to the selected word line.

At S75, the program voltage Vpgm may be reset to a voltage increased by a step voltage, and the reset program voltage may be applied to the selected word line. The program-enable voltage Val and the second program-inhibit voltage 2Vin may be selectively (e.g., sequentially) applied to bit lines (e.g., BL2) of the memory cells determined to be adjacent cells programmed MCa depending on the timing while the program voltage is applied to the selected word line. For example, the program-enable voltage Val and the second program-inhibit voltage 2Vin may be applied at different times to adjust the speed at which the threshold voltages of the adjacent cells programmed MCa are increased.

At S76, the program voltage Vpgm may be reset to a voltage increased by a step voltage, and the reset program voltage may be applied to the selected word line. The first program-inhibit voltage 1Vin may be applied to bit lines (e.g., BL3) of memory cells determined to be complete cells programmed MCc and unselected memory cells Unsel_MC while the program voltage Vpgm is applied to the selected word line Sel_WL.

At S74, the threshold voltages of the program initial memory cells MCi may be rapidly increased (at a first rate) due to the program-enable voltage Val applied to the bit lines.

At S75, the threshold voltages of program adjacent memory cells MCa may be increased more slowly (e.g., at a second rate less than the first rate) than the threshold voltages increased at S74, due to the program-enable voltage Val and the second program-inhibit voltage 2Vin that are selectively applied to the bit lines. That is, because the program-enable voltage Val is applied for a time shorter than the time the program-enable voltage Val is applied to the first bit line BL1, the rate at which the threshold voltage of the adjacent cell programmed MCa increases may be slower than the rate at which the threshold voltage of the initial cell programmed MCi increases. As a result, the speed at which the threshold voltages of the program adjacent memory cells MCa are increased may be adjusted.

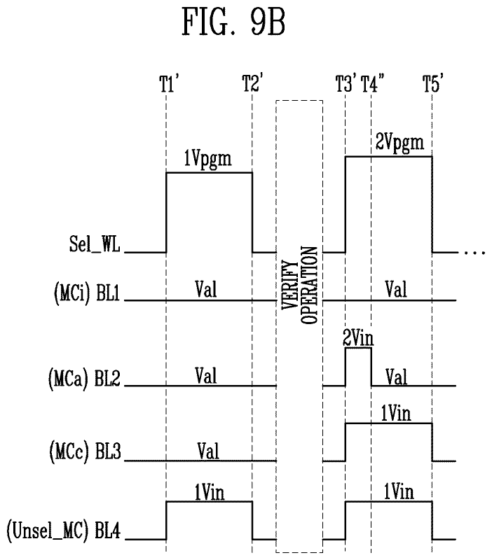

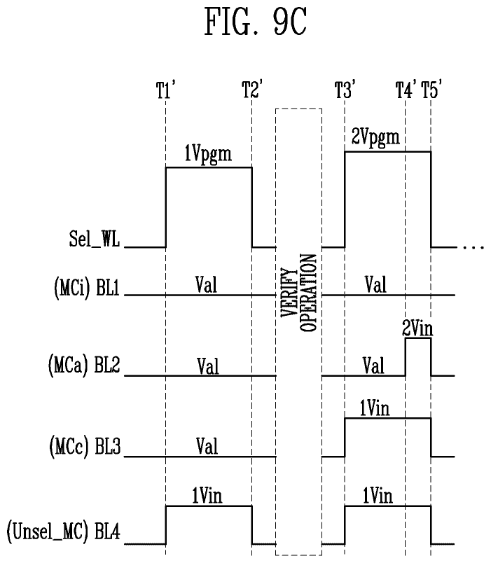

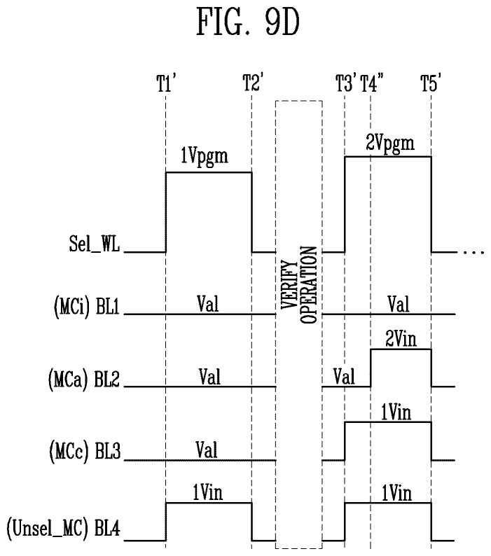

At S76, the memory cells are in the state in which programming has been completed or are unselected memory cells. Thus, the threshold voltages of memory cells are not increased due to the first program-inhibit voltage applied to the bit lines. The voltages applied to respective lines at S74, S75 and S76 will be described in detail later with reference to FIGS. 9A to 9D.

After the program voltage is applied to the selected word line during a certain time at S74, S75, and S76, a verify operation may be performed on the selected memory cells at S77. At S77, the verify operation may be performed in the same manner as the verify operation performed at S72. When a target verify operation performed at S77 has failed, S73 may be performed again. When the target verify operation performed at S77 has passed, the program operation on the selected page may be terminated.

FIG. 8 is a diagram illustrating the verify operation according to an embodiment of the present disclosure. The verify operation may be used to classify memory cells coupled to a selected word line based on voltages that are generated in response to an applied precharge voltage.

Referring to FIG. 8, a detailed method of the verify operation performed at S72 to S77 of FIG. 7 is illustrated. The verify operation may be performed during a period from a first time T1 to a fourth time T4. While the verify operation is performed, a ground voltage (i.e., 0 V) may be applied to the source line SL, a pass voltage Vpass may be applied to the unselected word lines Unsel_WL, and a turn-on voltage Von may be applied to the drain and source select lines DSL and SSL.

At the first time T1, a precharge voltage Vpre may be applied to all bit lines BL #. The precharge voltage Vpre may be a positive voltage greater than 0 V, and may be used to check voltage or current changes of the bit lines BL #depending on the states of the memory cells.

At the second time T2 at which the precharge voltage Vpre increases up to a target level, a pre-verify voltage Vpv is applied to a selected word line Sel_WL. The pre-verify voltage Vpv has a level less than that of a target verify voltage Vtv. For example, the pre-verify voltage Vpv is used to detect initial cells programmed MCi, and the target verify voltage Vtv is used to distinguish adjacent cells programmed MCa from complete cells programmed MCc. The ground voltage may be applied to the source line SL while the verify operation is performed.

The voltages of bit lines connected to memory cells having threshold voltages less than the pre-target voltage (e.g., Vp of FIG. 5) may become less than the precharge voltage Vpre while the pre-verify voltage Vpv is applied to the selected word line Sel_WL (T2-T3). During the period T2-T3, the memory cells connected to the bit lines, having voltages which are decreased, may be detected as initial cells programmed MCi.

At the third time T3, the target verify voltage Vtv may be applied to the selected word line Sel_WL. The voltages of bit lines connected to memory cells having threshold voltages less than the target voltage (e.g., Vt of FIG. 5) may become less than the precharge voltage Vpre while the target verify voltage Vtv is applied to the selected word line Sel_WL (T3-T4). During the period T3-T4, the memory cells connected to the bit lines, having voltages which are decreased, may be classified as adjacent cells programmed MCa. The rate at which the voltages of the adjacent cells programmed MCa decrease from the precharge voltage Vpre may be different from (e.g., have a steeper slope than) the rate at which the voltages of the initial cells programmed MCi decrease from the precharge voltage Vpre. During the period T3-T4, the memory cells connected to the bit lines maintained at the precharge voltage Vpre may be classified as complete cells programmed MCc.

As described above, during the verify operation, the pre-verify operation may be performed during the period from the second time T2 to the third time T3, and the target verify operation may be performed during the period from the third time T3 to the fourth time T4. Data sensed in the pre-verify operation and data sensed in the target-verify operation may be stored in latches included in a page buffer group (e.g., 140 of FIG. 1). The voltages to be applied to the bit lines in a next program loop may be determined depending on the sensed data stored in the page buffer group 140.

The verify operation on the selected page may pass or fail depending on the result of the target verify operation. For example, the pre-verify operation may be performed to distinguish the initial cells programmed MCi, and the target verify operation may be performed to distinguish the adjacent cells programmed MCa and the complete cells programmed MCc and determine whether the selected page has passed or failed the verify operation. Determining whether the verify operation has passed or failed may be identical to determining whether the program operation performed on the selected page is complete or incomplete.

FIGS. 9A to 9D are diagrams illustrating program operations according to a first embodiment of the present disclosure.

Referring to FIGS. 6, 7, and 9A, memory cells corresponding to first to third bit lines BL1 to BL3 are selected memory cells, and a memory cell corresponding to a fourth bit line BL4 is an unselected memory cell (e.g., see FIG. 6).

At a first time T1′ at which a program loop for a selected page starts, a first program voltage 1Vpgm may be applied to the selected word line Sel_WL, a program-enable voltage Val may be applied to the first to third bit lines BL1 to BL3, and a first program-inhibit voltage 1Vin may be applied to the fourth bit line BL4. A pass voltage Vpass may be applied to unselected word lines Unsel_MC, a ground voltage may be applied to a source line, and a turn-on voltage may be applied to drain and source select lines.

Because the memory cells connected to the first to third bit lines BL1 to BL3 are the selected memory cells MCi, MCa, and MCc, the threshold voltages of the selected memory cells may be increased due to the first program voltage 1Vpgm.

After the first program voltage 1Vpgm is applied during a period from the first time T1′ to a second time T2′, a verify operation may be performed on memory cells included in the selected page. The verify operation may correspond to the verify operation explained with reference to FIG. 8. The verify operation may classify (or determine the different states of) the memory cells included in the selected page. As a result of the verify operation, as described above with reference to FIG. 6, a memory cell connected to the first bit line BL1 is an initial cell programmed MCi, a memory cell connected to the second bit line BL2 is an adjacent cell programmed MCa, and a memory cell connected to the third bit line BL3 is a complete cell programmed MCc.

Depending on the result of the verify operation, when a next program loop starts, at a third time T3′, the program-enable voltage Val may be applied to the first bit line BL1, the second program-inhibit voltage 2Vin may be applied to the second bit line BL2, and the first program-inhibit voltage 1Vin may be applied to the third bit line BL3 and the fourth bit line BL4. The program-enable voltage Val applied to the initial cell programmed MCi may be applied for a different time (e.g., longer time) than the time at which the program-enable signal Vas is applied to the adjacent cell programmed MCa. This will cause the threshold voltages of the of the initial cell programmed MCi and the adjacent cell programmed MCa to increase at different rates.

More specifically, because the memory cell connected to the first bit line BL1 is the initial cell programmed MCi, the program-enable voltage Val may be applied to the first bit line BL1 so as to rapidly increase the threshold voltage of the initial cell programmed MCi. The program-enable voltage Val may be the lowest voltage among voltages set to be applied to bit lines during the program operation.

Because the memory cell connected to the second bit line BL2 is the adjacent cell programmed MCa, the second program-inhibit voltage 2Vin may be applied to the second bit line BL2 so as to increase the threshold voltage of the adjacent cell programmed MCa more slowly than the initial cell programmed MCi. This is because the second program-inhibit voltage 2Vin is applied for at least part of the time to the adjacent cell programmed MCa.

As shown, for example, in FIG. 9A, the second program-inhibit voltage 2Vin may be set to a voltage that is greater than the program-enable voltage Val and less than or equal to the first program-inhibit voltage 1Vin. Also, in the example of FIG. 9A, the second program-inhibit voltage 2Vin may be applied before the program-enable voltage Val and may be applied for a time longer than the second program-inhibit voltage 2Vin. Because the program-enable voltage Val is applied to the second bit line BL2 for a time shorter than the time the program-enable voltage Val is applied to the first bit line BL1, the rate at which the threshold voltage of the adjacent cell programmed MCa increases may be slower than the rate at which the threshold voltage of the initial cell programmed MCi increases.

Because the memory cell connected to the third bit line BL3 is the complete cell programmed MCc and the memory cell connected to the fourth bit line BL4 is the unselected memory cell Unsel_MC, the first program-inhibit voltage 1Vin may be applied to the third and fourth bit lines BL3 and BL4 so as to prevent the threshold voltages of the complete cell programmed MCc and the unselected memory cell Unsel_MC from further increasing. The first program-inhibit voltage 1Vin may be the highest voltage among voltages set to be applied to the bit lines during the program operation.

A second program voltage 2Vpgm may be applied to the selected word line Sel_WL. The second program voltage 2Vpgm may be set to a voltage higher than the first program voltage 1Vpgm by a step voltage. The second program voltage 2Vpgm may be set to be applied to the selected word line Sel_WL during a period from the third time T3′ to a fifth time T5′.

The first program-inhibit voltage 1Vin may also be applied to the third and fourth bit lines BL3 and BL4 during the period from the third time T3′ to the fifth time T5′.

As shown in FIG. 9A, the second program-inhibit voltage 2Vin may be applied to the second bit line BL2 during a time shorter than the time during which the second program voltage 2Vpgm or the first program-inhibit voltage 1Vin is applied. For example, the second program-inhibit voltage 2Vin may be applied to the second bit line BL2 during a period from the third time T3′ to the fourth time T4′. The period from the third to fourth times T3′-T4′ may be shorter than a period from the third to fifth times T3′-T5′ during which the second program voltage 2Vpgm is applied to the selected word line Sel_WL. During a period from the fourth to fifth times T4′-T5′, the program-enable voltage Val may be applied to the second bit line BL2.

Unlike the embodiment described with reference to FIG. 9A, when the second program-inhibit voltage 2Vin is applied to the second bit line BL2 during the same period T3′-T5′ as that of the first program-inhibit voltage 1Vin, the time during which the threshold voltage of the adjacent cell programmed MCa is increased is lengthened, with the result that the time required for the program operation may be excessively lengthened.

In the case of the embodiment described with reference to FIG. 9A, when the second program-inhibit voltage 2Vin is applied to the second bit line BL2 during the period from the third to fourth times T3′-T4′, and the program-enable voltage Val is applied to the second bit line BL2 during the period from the fourth to fifth times T4′-T5′, the time during which the threshold voltage of the adjacent cell programmed MCa is increased may be adjusted, with the result that the time required for the program operation may be shortened.

In the embodiment described with reference to FIG. 9A, the time during which the second program-inhibit voltage 2Vin is applied to the second bit line BL2 is shorter than the time during which the program-enable voltage Val is applied to the second bit line BL2. However, the times during which the second program-inhibit voltage 2Vin and the program-enable voltage Val are applied to the second bit line BI2 may be changed in various embodiments. Various embodiments for adjusting the second program-inhibit voltage 2Vin may be described as follows.

Referring to FIG. 9B, the second program-inhibit voltage 2Vin may be applied to the second bit line BL2 during a period from the third to fourth times T3′-T4″. The fourth time T4″ is earlier than the fourth time T4′ described above with reference to FIG. 9A. During the period from the fourth to fifth times T4″-T5′, the program-enable voltage Val may be applied to the second bit line BL2. The period from the third to fourth times T3′-T4″ may be shorter than the period from the fourth to fifth times T4″-T5′. Thus, in the case of the embodiment described above with reference to FIG. 9B, the time during which the program-enable voltage Val is applied to the second bit line BL2 is longer than the time during which the second program-inhibit voltage 2Vin is applied thereto. As a result, the time required for the program operation may be shortened compared to the embodiment described above with reference to FIG. 9A. Because a method of applying voltages to the remaining lines is the same as the embodiment described above with reference to FIG. 9A, except for the time during which the second program-inhibit voltage 2Vin and the program-enable voltage Val are applied to the second bit line BL2, repeated description thereof will be omitted.

Referring to FIG. 9C, during a period from third to fifth times T3′-T5′, the program-enable voltage Val is first applied to the second bit line BL2, and thereafter the second program-inhibit voltage 2Vin may be applied thereto. For example, the program-enable voltage Val is applied to the second bit line BL2 during the period from the third to fourth times T3′-T4′, and the second program-inhibit voltage 2Vin may be applied to the second bit line BL2 during a period from fourth to fifth times T4′-T5′. In this embodiment, the time (T3′-T4′) the program-enable voltage is applied to the second bit line BL2 is longer than the time the second program-inhibit voltage 2Vin is applied to the second bit line BL2, e.g., time T3′-T4′ is greater time T4′-T5′. Therefore, the threshold voltage of the adjacent cell programmed MCa may be increased relatively rapidly during the period from the third to fourth times T3′-T4′, and the threshold voltage of the adjacent cell programmed MCa may be increased relatively slowly during the period from the fourth to fifth times T4′-T5′. Because the method of applying voltages to the remaining lines is the same as the embodiment described above with reference to FIG. 9A, except for the time during which the program-enable voltage Val and the second program-inhibit voltage 2Vin are applied to the second bit line BL2, repeated description thereof will be omitted.

Referring to FIG. 9D, the program-enable voltage Val may be applied to the second bit line BL2 during a period from third to fourth times T3′-T4″, and the second program-inhibit voltage 2Vin may be applied to the second bit line BL2 during a period from the fourth to fifth times T4″-T5′. In this case, the time (T4″-T5′) the second program-inhibit voltage 2Vin is applied to the second bit line BL2 is longer than the time (T3′-T4) at which the program-enable voltage Val is applied. Therefore, the threshold voltage of the adjacent cell programmed MCa may be increased relatively rapidly during the period from the third to fourth times T3′-T4″, and the threshold voltage of the adjacent cell programmed MCa may be increased relatively slowly during the period from the fourth to fifth times T4″-T5′. Because the method of applying voltages to the remaining lines is the same as the embodiment described above with reference to FIG. 9A, except for the time during which the program-enable voltage Val and the second program-inhibit voltage 2Vin are applied to the second bit line BL2, repeated description thereof will be omitted.

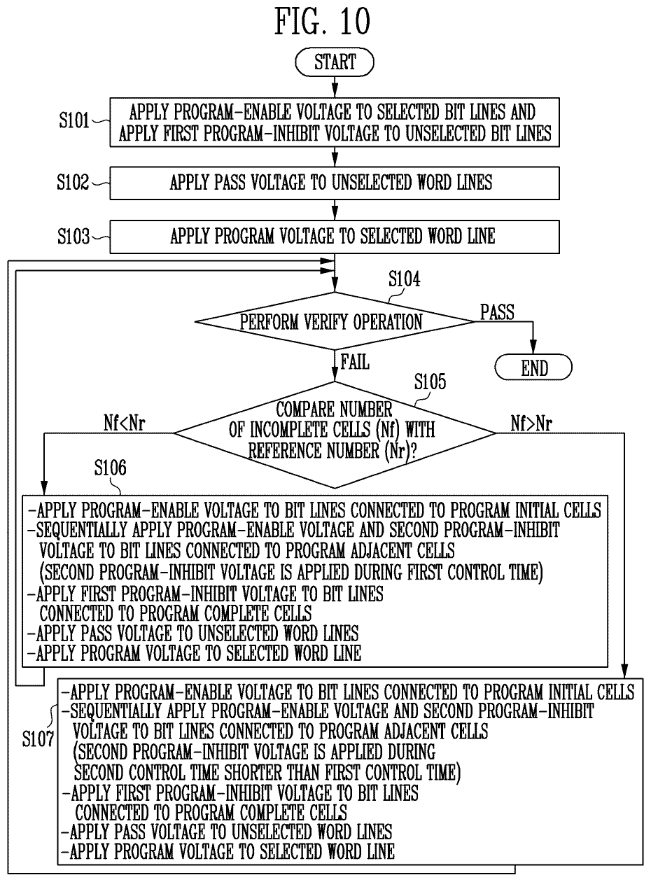

FIG. 10 is a flowchart illustrating a program operation according to a second embodiment of the present disclosure.

Referring to FIG. 10, when a program operation on a selected memory block starts, at S101, a program-enable voltage Val may be applied to selected bit lines connected to the selected memory block, and a first program-inhibit voltage 1Vin may be applied to unselected bit lines.

A pass voltage Vpass may be applied to unselected word lines among word lines connected to the selected memory block at S102, and a program voltage Vpgm may be applied to the selected word line at S103. The selected word line Sel_WL may be a word line connected to a selected page among pages included in the selected memory block.

After the program voltage Vpgm is applied to the selected word line Sel_WL during a certain time, at S104, a verify operation may be performed on memory cells included in the selected page. The verify operation may be performed using a method described above with reference to FIG. 8. For example, as described above with reference to FIG. 8, during the verify operation, a pre-verify operation and a target verify operation may be performed. Therefore, based on the verify operation at S104, each of the memory cells included in the selected page may be classified as a program initial cell, a program adjacent cell, or a program complete cell.

During the verify operation performed at S104, the number of incomplete cells Nf, detected from the result of the target verify operation, is compared with a reference number Nr at S105. The number of incomplete cells may be the sum of the number of initial cells programmed MCi and the number of adjacent cells programmed MCa. For example, the control circuit (e.g., 170 of FIG. 1) may calculate the number of incomplete cells Nf by summing the number of initial cells programmed MCi and the number of adjacent cells programmed MCa based on data that is sensed and stored in the page buffer group (e.g., 140 of FIG. 1) during the verify operation.

The control circuit 170 may compare the number of incomplete cells Nf with the prestored reference number Nr. The reference number Nr may be set differently depending on the memory device. According to an embodiment, instead of the number of incomplete cells Nf, the number of complete cells programmed may be counted, wherein the reference number corresponding to the number of pass cells may be different from the reference number Nr corresponding to the number of incomplete cells. In embodiments to be described below, a method of comparing the number of incomplete cells Nf with the reference number Nr will be described.

When it is determined at S105 that the number of incomplete cells Nf is less than the reference number Nr (Nf<Nr), at S106, the program-enable voltage Val is applied to bit lines connected to initial cells programmed MCi, the program-enable voltage Val and a second program-inhibit voltage 2Vin are sequentially applied to bit lines connected to the adjacent cells programmed MCa, the first program-inhibit voltage 1Vin is applied to bit lines connected to complete cells programmed, the pass voltage is applied to unselected word lines Unsel_MC, and the program voltage Vpgm is applied to a selected word line Sel_WL. The program voltage Vpgm applied to the selected word line may be increased by a step voltage as the number of program loops increases.

The program-enable voltage Val and the second program-inhibit voltage 2Vin that are applied to the bit lines connected to the adjacent cells programmed MCa may be sequentially applied to the bit lines, while the program voltage Vpgm is applied to the selected word line. The order in which the program-enable voltage Val and the second program-inhibit voltage 2Vin are applied to the bit lines connected to the adjacent cells programmed MCa, and the times during which the voltages are applied, may be changed. Here, it is assumed that the time during which the second program-inhibit voltage 2Vin is applied to and maintained in the bit lines connected to the adjacent cells programmed MCa is a first control time CT1.

When it is determined at S105 that the number of incomplete cells Nf is greater than the reference number Nr (Nf>Nr), the program-enable voltage Val is applied to bit lines connected to initial cells programmed MCi, the program-enable voltage Val and a second program-inhibit voltage 2Vin are sequentially applied to bit lines connected to the adjacent cells programmed MCa in a predetermined order, the first program-inhibit voltage 1Vin is applied to bit lines connected to complete cells programmed MCc, the pass voltage is applied to unselected word lines Unsel_WL, and the program voltage Vpgm is applied to a selected word line. The program voltage applied to the selected word line Sel_WL may be increased by a step voltage as the number of program loops increases.

When it is determined at S105 that the number of incomplete cells Nf is equal to the reference number Nr, S106 or S107 may be set to be performed. In an embodiment, the time during which the second program-inhibit voltage 2Vin is applied to and maintained in the bit lines connected to the adjacent cells programmed MCa is a second control time CT2 shorter than the first control time at S107.

After S106 or S107 is performed, the verify operation on the selected memory cells may be performed once again at S104. S104 to S107 may be repeated until the verify operation performed at step S104 passes.

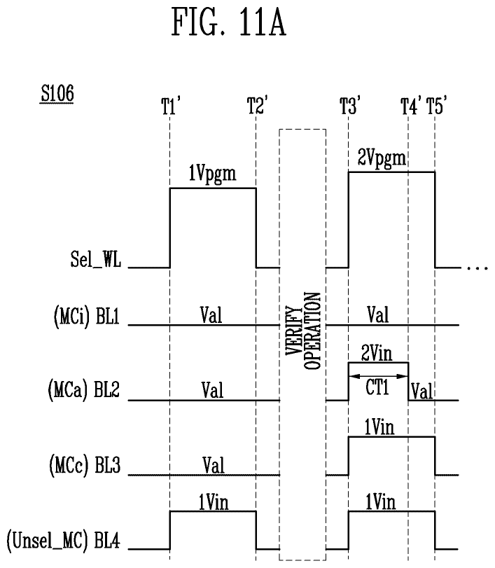

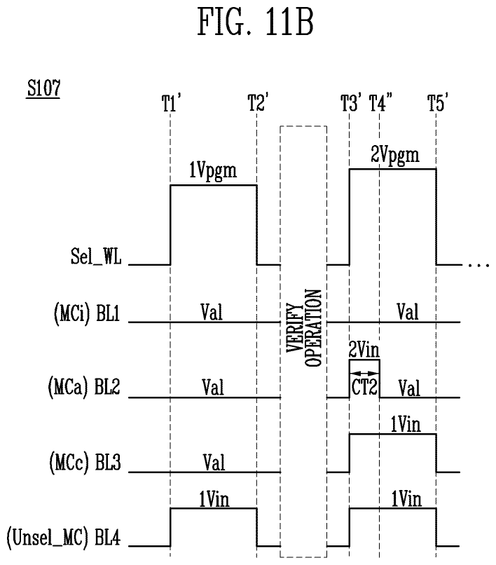

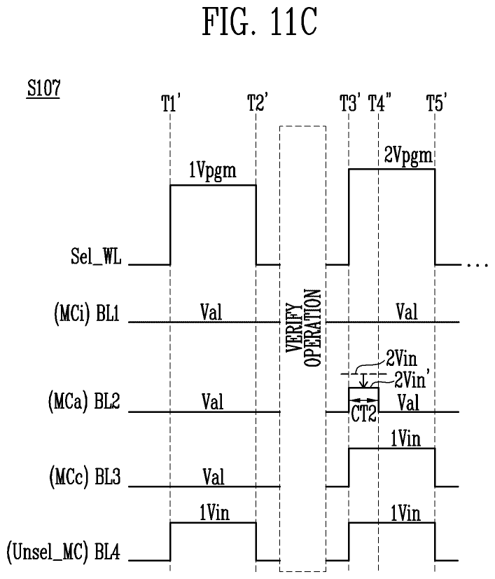

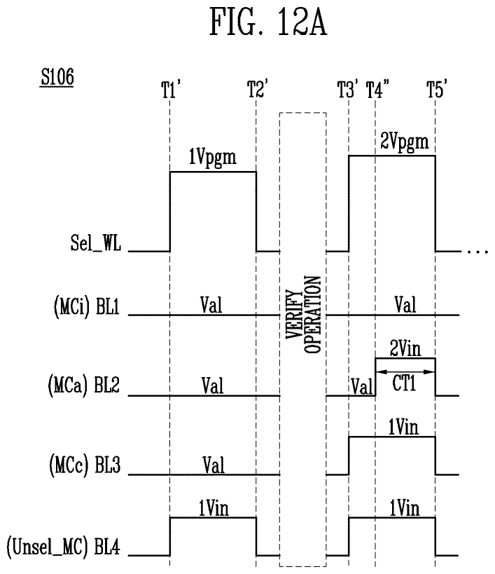

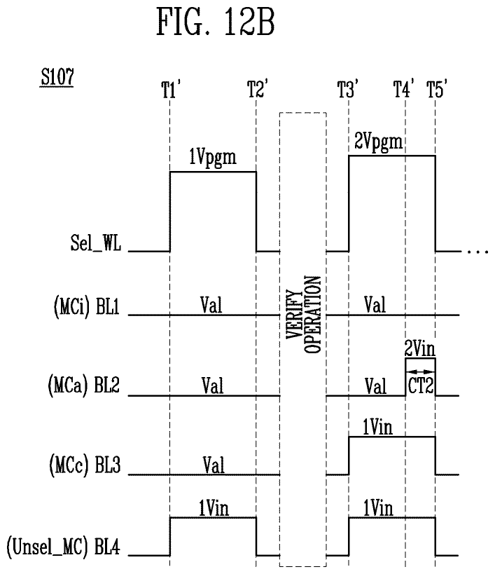

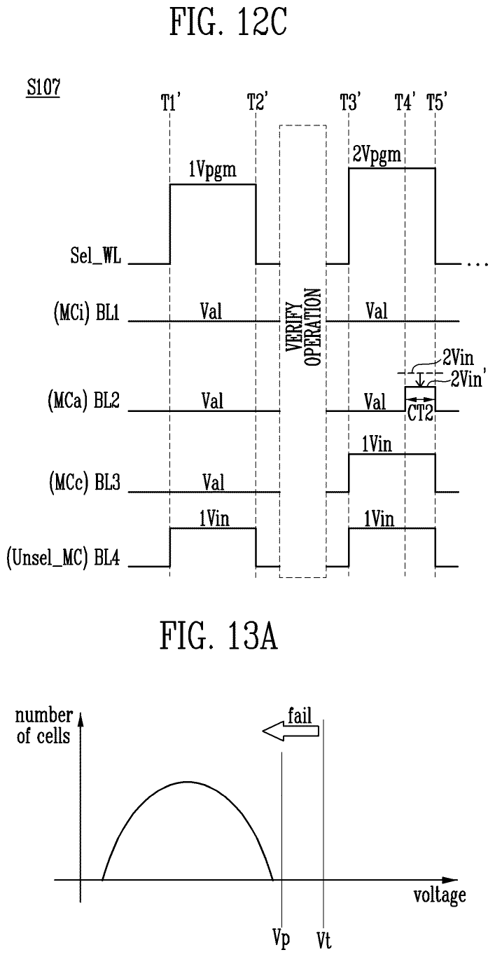

FIGS. 11A to 11C and 12A to 12C are diagrams illustrating program operations according to a second embodiment of the present disclosure.

FIGS. 11A and 12A illustrate different embodiments corresponding to S106 of FIG. 10, FIGS. 11B and 12B illustrate different embodiments corresponding to S107 of FIG. 10, and FIGS. 11C and 12C illustrate other embodiments corresponding to S107 of FIG. 10. That is, when S106 of FIG. 10 is set to be performed as in the case of the embodiment illustrated in FIG. 11A, S107 of FIG. 10 may be performed, as in the case of the embodiment illustrated in FIG. 11B. In other embodiments, when S106 of FIG. 10 is set to be performed as in the case of the embodiment shown in FIG. 12A, S107 of FIG. 10 may be performed, as in the case of the embodiment shown in FIG. 12B. FIGS. 11C and 12C illustrate embodiments in which voltages to be applied to bit lines are adjusted in comparison with step S106.

Referring to FIGS. 6, 10, and 11A, in one embodiment, memory cells corresponding to first to third bit lines BL1 to BL3 are selected memory cells, and a memory cell corresponding to a fourth bit line BL4 is an unselected memory cell. Further, in one embodiment, memory cells (e.g., MCi, MCa, and MCc) corresponding to first to third bit lines BL1 to BL3 are selected memory cells, and a memory cell Unsel_MC corresponding to a fourth bit line BL4 is an unselected memory cell (e.g., see FIG. 6).

At a first time T1′ at which a program loop for a selected page starts, a first program voltage 1Vpgm may be applied to the selected word line Sel_WL, a program-enable voltage Val may be applied to the first to third bit lines BL1 to BL3, and a first program-inhibit voltage 1Vin may be applied to the fourth bit line BL4. A pass voltage may be applied to unselected word lines, a ground voltage may be applied to a source line, and a turn-on voltage may be applied to drain and source select lines. Because the memory cells connected to the first to third bit lines BL1 to BL3 are the selected memory cells, the threshold voltages of the selected memory cells may be increased due to the first program voltage 1Vpgm.

After the first program voltage 1Vpgm is applied during a period from the first to second times T1′-T2′, a verify operation may be performed on memory cells included in the selected page to classify the types of memory cells coupled to the first to third bit lines BL1 to BL3.

The verify operation may be performed using a method described above with reference to FIG. 8. As a result of the verify operation, as described above with reference to FIG. 6, it is assumed that a memory cell connected to the first bit line BL1 is an initial cell programmed MCi, a memory cell connected to the second bit line BL2 is an adjacent cell programmed MCa, and a memory cell connected to the third bit line BL3 is a complete cell programmed MCc.

Depending on the result of the verify operation, when a next program loop starts, at a third time T3′, the program-enable voltage Val may be applied to the first bit line BL1, the second program-inhibit voltage 2Vin may be applied to the second bit line BL2, and the first program-inhibit voltage 1Vin may be applied to the third bit line BL3 and the fourth bit line BL4. The program-enable voltage Val, the second program-inhibit voltage 2Vin, and the first program-inhibit voltage 1Vin may be applied during a time when a second program voltage 2Vpgm is applied to the selected word line Sel_WL.

Because the memory cell connected to the first bit line BL1 is the initial cell programmed MCi, the program-enable voltage Val may be applied to the first bit line BL1 so as to rapidly increase the threshold voltage of the initial cell programmed MCi. The program-enable voltage Val may be the lowest voltage among voltages set to be applied to bit lines during the program operation.

Because the memory cell connected to the second bit line BL2 is the adjacent cell programmed MCa, the second program-inhibit voltage 2Vin may be applied to the second bit line BL2 so as to increase the threshold voltage of the adjacent cell programmed MCa more slowly than the initial cell programmed MCi. Thus, the threshold voltage of the initial cell programmed MCi may be increased at a first rate and the threshold voltage of the adjacent cell programmed MCa may be increased at a second rate lower than the first rate. The second program-inhibit voltage 2Vin may be set to a voltage that is higher than the program-enable voltage Val and lower than or equal to the first program-inhibit voltage 1Vin.

Because the memory cell connected to the third bit line BL3 is the complete cell programmed MCc and the memory cell connected to the fourth bit line BL4 is the unselected memory cell Unsel_MC, the first program-inhibit voltage 1Vin may be applied to the third and fourth bit lines BL3 and BL4 so as to prevent the threshold voltages of the complete cell programmed MCc and the unselected memory cell Unsel_MC from further increasing. The first program-inhibit voltage 1Vin may be the highest voltage among voltages set to be applied to the bit lines during the program operation.

A second program voltage 2Vpgm may be applied to the selected word line Sel_WL. The second program voltage 2Vpgm may be set to a voltage greater than the first program voltage 1Vpgm by a step voltage. The second program voltage 2Vpgm may be set to be applied to the selected word line Sel_WL during a period from the third time T3′ to a fifth time T5′.

The first program-inhibit voltage 1Vin may also be applied to the third and fourth bit lines BL3 and BL4 during the period from the third time T3′ to the fifth time T5′, e.g., during the same length of time that the second program voltage 2Vpgm is applied.

The second program-inhibit voltage 2Vin may be applied to the second bit line BL2 during a time shorter than the time during which the second program voltage 2Vpgm or the first program-inhibit voltage 1Vin is applied. In the operation described above with reference to FIG. 10, at S106, the second program-inhibit voltage 2Vin may be applied to the second bit line BL2 during a first control time CT1. That is, when the number of incomplete cells Nf detected in the verify operation is less than the reference number Nr, the time during which the second program-inhibit voltage 2Vin is applied to the second bit line BL2 may be defined as the first control time CT1. The number of incomplete cells may be the sum of the number of initial cells programmed MCi and the number of adjacent cells programmed MCa coupled to the selected word line Sel_WL. That is, the fact that the number of incomplete cells Nf is less than the reference number Nr may mean that the number of complete cells programmed is larger. In other words, the fact that the number of incomplete cells Nf is less than the reference number Nr may mean that the number of cells, the threshold voltages of which are to be increased, is smaller than the number of complete cells programmed. The control circuit (e.g., 170 of FIG. 1) may control the page buffer group (e.g., 140 of FIG. 1) so that the second program-inhibit voltage 2Vin is applied to the second bit line BL2 during a time longer than that of the program-enable voltage Val applied to the second bit line BL2.

The first control time CT1 may be the period from the third time T3′ to the fourth time T4′. Since the fourth time T4′ is earlier than the fifth time T5′, the first control time CT1 may be shorter than the period from the third time T3′ to the fifth time T5′. The first control time CT1 may be changed between the third time T3′ and the fifth time T5′. During a period from the fourth to fifth times T4′-T5′, the program-enable voltage Val may be applied to the second bit line BL2 to increase the threshold voltage of the adjacent cell programmed MCa at the slower rate.

Referring to FIGS. 6, 10, and 11B, in one embodiment, memory cells corresponding to first to third bit lines BL1 to BL3 are selected memory cells, and a memory cell corresponding to a fourth bit line BL4 is an unselected memory cell. Further, in one embodiment, memory cells corresponding to first to third bit lines BL1 to BL3 are selected memory cells, and a memory cell corresponding to a fourth bit line BL4 is an unselected memory cell.

At a first time T1′ at which a program loop for a selected page starts, a first program voltage 1Vpgm may be applied to the selected word line Sel_WL, a program-enable voltage Val may be applied to the first to third bit lines BL1 to BL3, and a first program-inhibit voltage 1Vin may be applied to the fourth bit line BL4. A pass voltage may be applied to unselected word lines, a ground voltage may be applied to a source line, and a turn-on voltage may be applied to drain and source select lines. Because the memory cells connected to the first to third bit lines BL1 to BL3 are the selected memory cells, the threshold voltages of the selected memory cells may be increased due to the first program voltage 1Vpgm.

After the first program voltage 1Vpgm is applied during a period from the first to second times T1′-T2′, a verify operation may be performed on memory cells included in the selected page. The verify operation may be performed using a method described above with reference to FIG. 8 in order to classify the memory cells coupled to the selected word line Sel_WL as initial cells programmed MCi, adjacent cells programmed MCa, and complete cells programmed MCc.

As a result of the verify operation, as described above with reference to FIG. 6, a memory cell connected to the first bit line BL1 is an initial cell programmed MCi, a memory cell connected to the second bit line BL2 is an adjacent cell programmed MCa, and a memory cell connected to the third bit line BL3 is a complete cell programmed MCc.

Depending on the result of the verify operation, when a next program loop starts, at a third time T3′, the program-enable voltage Val may be applied to the first bit line BL1, the second program-inhibit voltage 2Vin may be applied to the second bit line BL2, and the first program-inhibit voltage 1Vin may be applied to the third bit line BL3 and the fourth bit line BL4.

Because the memory cell connected to the first bit line BL1 is an initial cell programmed MCi, the program-enable voltage Val may be applied to the first bit line BL1 so as to rapidly increase the threshold voltage of the initial cell programmed MCi. The program-enable voltage Val may be the lowest voltage among voltages set to be applied to bit lines during the program operation.

Because the memory cell connected to the second bit line BL2 is an adjacent cell programmed MCa, the second program-inhibit voltage 2Vin may be applied to the second bit line BL2 so as to increase the threshold voltage of the adjacent cell programmed MCa more slowly than the initial cell programmed MCi. The second program-inhibit voltage 2Vin may be set to a voltage that is higher than the program-enable voltage Val and lower than or equal to the first program-inhibit voltage 1Vin.

Because the memory cell connected to the third bit line BL3 is a complete cell programmed MCc and the memory cell connected to the fourth bit line BL4 is an unselected memory cell Unsel_MC, the first program-inhibit voltage 1Vin may be applied to the third and fourth bit lines BL3 and BL4 so as to prevent the threshold voltages of the complete cell programmed MCc and the unselected memory cell Unsel_MC from further increasing. The first program-inhibit voltage 1Vin may be the highest voltage among voltages set to be applied to the bit lines during the program operation.

A second program voltage 2Vpgm may be applied to the selected word line Sel_WL. The second program voltage 2Vpgm may be set to a voltage higher than the first program voltage 1Vpgm by a step voltage. The second program voltage 2Vpgm may be set to be applied to the selected word line Sel_WL during a period from the third time T3′ to a fifth time T5′.

The first program-inhibit voltage 1Vin may also be applied to the third and fourth bit lines BL3 and BL4 during the period from the third time T3′ to the fifth time T5′.

The second program-inhibit voltage 2Vin may be applied to the second bit line BL2 during a time shorter than the time during which the second program voltage 2Vpgm or the first program-inhibit voltage 1Vin is applied. In the operation described above with reference to FIG. 10, at S107, the second program-inhibit voltage 2Vin may be applied to the second bit line BL2 during a second control time CT2 shorter than the first control time CT1 in FIG. 11A. That is, when the number of incomplete cells Nf detected in the verify operation is greater than the reference number Nr, the time during which the second program-inhibit voltage 2Vin is applied to the second bit line BL2 may be defined as the second control time CT2.

That is, the fact that the number of incomplete cells Nf is greater than the reference number Nr may mean that the number of passed cells is smaller, i.e., the fact that the number of incomplete cells Nf is greater than the reference number Nr may mean that the number of cells, the threshold voltages of which are to be increased, is larger. Therefore, the control circuit (e.g., 170 of FIG. 1) may control the page buffer group (e.g., 140 of FIG. 1) so that the second program-inhibit voltage 2Vin is applied to the second bit line BL2 during a time shorter than that of the program-enable voltage Val. Because the program-enable voltage Val is applied to the second bit line BL2 for a time shorter than the time that the program-enable voltage Val is applied to the first bit line BL1, the rate at which the threshold voltage of the adjacent cell programmed MCa increases may be slower than the rate at which the threshold voltage of the initial cell programmed MCi increases.

The second control time CT2 may be the period from the third time T3′ to the fourth time T4″. Since the fourth time T4″ is earlier than the fifth time T5′, the second control time CT2 may be shorter than the period from the third time T3′ to the fifth time T5′. The second control time CT2 may be changed between the third time T3′ and the fifth time T5′. During a period from the fourth to fifth times T4″-T5′, the program-enable voltage Val may be applied to the second bit line BL2.

Referring to FIGS. 6, 10, and 11C, as described above with reference to FIG. 11B, when the number of incomplete cells Vf is greater than a reference number Vr, the time during which the second program-inhibit voltage is applied to the second bit line BL2 may be shortened to the period from the third time T3′ to the fourth time T4″, which corresponds to the second control time CT2. In this embodiment, the level of the second program-inhibit voltage 2Vin applied to the second bit line BL2 may be adjusted to a lower level 2Vin′. Thus, in this embodiment, both the time and the level of the second program-inhibit voltage applied to the second bit line BL2 may be simultaneously adjusted. For example, the second program-inhibit voltage 2Vin′ described with reference to FIG. 11C may have a level that is less than the second program-inhibit voltage 2Vin, described with reference to FIG. 11B, and greater than 0 V (and the program-enable voltage Val), and may be applied to the second bit line BL2 between the third time T3′ and the fourth time T4″.

Referring to FIGS. 6, 10, and 12A, in one embodiment, memory cells corresponding to first to third bit lines BL1 to BL3 are selected memory cells, and a memory cell corresponding to a fourth bit line BL4 is an unselected memory cell. Further, in one embodiment, memory cells corresponding to first to third bit lines BL1 to BL3 are selected memory cells, and a memory cell corresponding to a fourth bit line BL4 is an unselected memory cell. In this embodiment, the program-enable voltage Val is applied to the second bit line BL2 before the second program-inhibit voltage 2Vin is applied to the second bit line BL2.

At a first time T1′ at which a program loop for a selected page starts, a first program voltage 1Vpgm may be applied to the selected word line Sel_WL, a program-enable voltage Val may be applied to the first to third bit lines BL1 to BL3, and a first program-inhibit voltage 1Vin may be applied to the fourth bit line BL4. A pass voltage may be applied to unselected word lines, a ground voltage may be applied to a source line, and a turn-on voltage may be applied to drain and source select lines.

Because the memory cells connected to the first to third bit lines BL1 to BL3 are the selected memory cells, the threshold voltages of the selected memory cells may be increased due to the first program voltage 1Vpgm.

After the first program voltage 1Vpgm is applied during a period from the first to second times T1′-T2′, a verify operation may be performed on memory cells included in the selected page. The verify operation may be performed using a method described above with reference to FIG. 8 to classify the memory cells coupled to the selected word line Sel_WL as initial cells programmed MCi, adjacent cells programmed MCa, and complete cells programmed MCc. That is, as a result of the verify operation, as described above with reference to FIG. 6, it is assumed that a memory cell connected to the first bit line BL1 is an initial cell programmed MCi, a memory cell connected to the second bit line BL2 is an adjacent cell programmed MCa, and a memory cell connected to the third bit line BL3 is a complete cell programmed MCc.

Depending on the result of the verify operation, when a next program loop starts, at a third time T3′, the program-enable voltage Val may be applied to the first bit line BL1, the program-enable voltage Val may be applied to the second bit line BL2, and the first program-inhibit voltage 1Vin may be applied to the third bit line BL3 and the fourth bit line BL4.

The memory cell connected to the first bit line BL1 is an initial cell programmed MCi, and thus the program-enable voltage Val may be applied to the first bit line BL1 so as to rapidly increase the threshold voltage of the initial cell programmed MCi during a period from the third to fifth times T3′-T5′. The program-enable voltage Val may be the lowest voltage among voltages set to be applied to bit lines during the program operation.

Because the memory cell connected to the second bit line BL2 is an adjacent cell programmed MCa, in this embodiment, the program-enable voltage Val is applied to the second bit line BL2 first, and then the second program-inhibit voltage 2Vin is applied thereto so as to increase the threshold voltage of the adjacent cell programmed MCa more slowly than the initial cell programmed MCi. The threshold voltage of the adjacent cell programmed MCa increases more slowly than the threshold voltage of the initial cell programmed MCi because the time that the program-enable voltage Val is applied to the second bit line BL2 is less than the time the program-enable voltage Val is applied to the first bit line BL1. The second program-inhibit voltage 2Vin may be set to a voltage that is greater than the program-enable voltage Val and less than or equal to the first program-inhibit voltage 1Vin.

Because the memory cell connected to the third bit line BL3 is the complete cell programmed MCc and the memory cell connected to the fourth bit line BL4 is the unselected memory cell Unsel_MC, the first program-inhibit voltage 1Vin may be applied to the third and fourth bit lines BL3 and BL4 so as to prevent the threshold voltages of the complete cell programmed MCc and the unselected memory cell Unsel_MC from further increasing. The first program-inhibit voltage 1Vin may be the highest voltage among voltages set to be applied to the bit lines during the program operation.

A second program voltage 2Vpgm may be applied to the selected word line Sel_WL. The second program voltage 2Vpgm may be set to a voltage greater than the first program voltage 1Vpgm by a step voltage. The second program voltage 2Vpgm may be set to be applied to the selected word line Sel_WL during a period from the third time T3′ to a fifth time T5′.

The first program-inhibit voltage 1Vin may also be applied to the third and fourth bit lines BL3 and BL4 during the period from the third time T3′ to the fifth time T5′.

The second program-inhibit voltage 2Vin may be applied to the second bit line BL2 during a time shorter than the time during which the second program voltage 2Vpgm or the first program-inhibit voltage 1Vin is applied. In the operation described above with reference to FIG. 10, at S106, the second program-inhibit voltage 2Vin may be applied to the second bit line BL2 during a first control time CT1. That is, when the number of incomplete cells Nf detected in the verify operation is less than the reference number Nr, the time during which the second program-inhibit voltage 2Vin is applied to the second bit line BL2 may be defined as the first control time CT1. That is, the fact that the number of incomplete cells Nf is less than the reference number Nr may mean that the number of complete cells programmed is larger. In other words, the fact that the number of incomplete cells Nf is less than the reference number Nr may mean that the number of cells, the threshold voltages of which are to be increased, is smaller. Therefore, the control circuit (e.g., 170 of FIG. 1) may control the page buffer group (e.g., 140 of FIG. 1) so that the second program-inhibit voltage 2Vin is applied to the second bit line BL2 during a time longer than that of the program-enable voltage Val.

The first control time CT1 may be a period from a fourth time T4″ to a fifth time T5′. Since the fourth time T4″ is earlier than the fifth time T5′, the first control time CT1 may be shorter than the period from the third time T3′ to the fifth time T5′. The first control time CT1 may be changed between the third time T3′ and the fifth time T5′.

Referring to FIGS. 6, 10, and 12B, it is assumed that memory cells corresponding to first to third bit lines BL1 to BL3 are selected memory cells, and a memory cell corresponding to a fourth bit line BL4 is an unselected memory cell. It is also assumed that memory cells corresponding to first to third bit lines BL1 to BL3 are selected memory cells, and a memory cell corresponding to a fourth bit line BL4 is an unselected memory cell.

At a first time T1′ at which a program loop for a selected page starts, a first program voltage 1Vpgm may be applied to the selected word line Sel_WL, a program-enable voltage Val may be applied to the first to third bit lines BL1 to BL3, and a first program-inhibit voltage 1Vin may be applied to the fourth bit line BL4. A pass voltage may be applied to unselected word lines, a ground voltage may be applied to a source line, and a turn-on voltage may be applied to drain and source select lines.

Because the memory cells connected to the first to third bit lines BL1 to BL3 are the selected memory cells, the threshold voltages of the selected memory cells may be increased due to the first program voltage 1Vpgm.

After the first program voltage 1Vpgm is applied during a period from the first to second times T1′-T2′, a verify operation may be performed on memory cells included in the selected page. The verify operation may be performed using a method described above with reference to FIG. 8 to classify the selected memory cells as initial cells programmed MCi, adjacent cells programmed MCa, and complete cells programmed MCc. As a result of the verify operation, as described above with reference to FIG. 6, a memory cell connected to the first bit line BL1 is an initial cell programmed MCi, a memory cell connected to the second bit line BL2 is an adjacent cell programmed MCa, and a memory cell connected to the third bit line BL3 is a complete cell programmed MCc.

Depending on the result of the verify operation, when a next program loop starts, at a third time T3′, the program-enable voltage Val may be applied to the first bit line BL1, the program-enable voltage Val may be applied to the second bit line BL2, and the first program-inhibit voltage 1Vin may be applied to the third bit line BL3 and the fourth bit line BL4.

Because the memory cell connected to the first bit line BL1 is an initial cell programmed MCi, the program-enable voltage Val may be applied to the first bit line BL1 so as to rapidly increase the threshold voltage of the initial cell programmed MCi. The program-enable voltage Val may be the lowest voltage among voltages set to be applied to bit lines during the program operation.

Because the memory cell connected to the second bit line BL2 is the adjacent cell programmed MCa, the program-enable voltage Val is applied to the second bit line BL2 first, and then the second program-inhibit voltage 2Vin is applied thereto so as to increase the threshold voltage of the adjacent cell programmed MCa more slowly than the initial cell programmed MCi. The slower increase in the threshold voltage results from the fact that the program-enable voltage Val is applied to the second bit line BL2 for a time shorter than the time the program-enable voltage Val is applied to the first bit line BL1. The second program-inhibit voltage 2Vin may be set to a voltage that is greater than the program-enable voltage Val and less than or equal to the first program-inhibit voltage 1Vin.

Because the memory cell connected to the third bit line BL3 is the complete cell programmed MCc and the memory cell connected to the fourth bit line BL4 is the unselected memory cell Unsel_MC, the first program-inhibit voltage 1Vin may be applied to the third and fourth bit lines BL3 and BL4 so as to prevent the threshold voltages of the complete cell programmed MCc and the unselected memory cell Unsel_MC from further increasing. The first program-inhibit voltage 1Vin may be the highest voltage among voltages set to be applied to the bit lines during the program operation.

A second program voltage 2Vpgm may be applied to the selected word line Sel_WL. The second program voltage 2Vpgm may be set to a voltage greater than the first program voltage 1Vpgm by a step voltage. The second program voltage 2Vpgm may be set to be applied to the selected word line Sel_WL during a period from the third time T3′ to a fifth time T5′.

The first program-inhibit voltage 1Vin may also be applied to the third and fourth bit lines BL3 and BL4 during the period from the third time T3′ to the fifth time T5′.

The second program-inhibit voltage 2Vin may be applied to the second bit line BL2 during a time shorter than the time during which the second program voltage 2Vpgm or the first program-inhibit voltage 1Vin is applied. In the operation described above with reference to FIG. 10, at S107, the second program-inhibit voltage 2Vin may be applied to the second bit line BL2 during a second control time CT2 shorter than the first control time CT1 in FIG. 12A. That is, when the number of incomplete cells Nf detected in the verify operation is greater than the reference number Nr, the time during which the second program-inhibit voltage 2Vin is applied to the second bit line BL2 may be defined as the second control time CT2. That is, the fact that the number of incomplete cells Nf is greater than the reference number Nr may mean that the number of complete cells programmed is smaller, i.e., the fact that the number of incomplete cells Nf is greater than the reference number Nr may mean that the number of cells, the threshold voltages of which are to be increased, is larger. Therefore, the control circuit (e.g., 170 of FIG. 1) may control the page buffer group (e.g., 140 of FIG. 1) so that the second program-inhibit voltage 2Vin is applied to the second bit line BL2 during a time shorter than that of the program-enable voltage Val.

The second control time CT2 may be a period from a fourth time T4′ to a fifth time T5′. Since the fourth time T4′ is earlier than the fifth time T5′, the second control time CT2 may be shorter than the period from the third time T3′ to the fifth time T5′. The second control time CT2 may be changed between the third time T3′ and the fifth time T5′.

Referring to FIGS. 6, 10, and 12C, as described above with reference to FIG. 12B, when the number of incomplete cells Vf is greater than a reference number Vr, the time during which the second program-inhibit voltage is applied to the second bit line BL2 may be shortened to the period from the third time T4′ to the fourth time T5′, which corresponds to the second control time CT2. In this embodiment, the level of the second program-inhibit voltage 2Vin applied to the second bit line BL2 may be adjusted to a lower level 2Vin′. Thus, in this embodiment, both the time and the level of the second program-inhibit voltage applied to the second bit line BL2 may be simultaneously adjusted. For example, the second program-inhibit voltage 2Vin′ described with reference to FIG. 12C may have a level that is less than the second program-inhibit voltage 2Vin, described with reference to FIG. 12B, and greater than 0 V (and the program-enable voltage Val), and may be applied to the second bit line BL2 between the third time T4′ and the fourth time T5′.

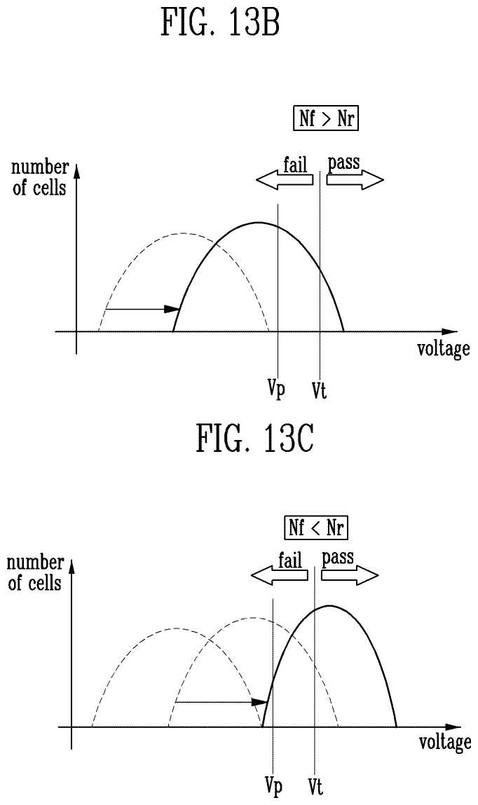

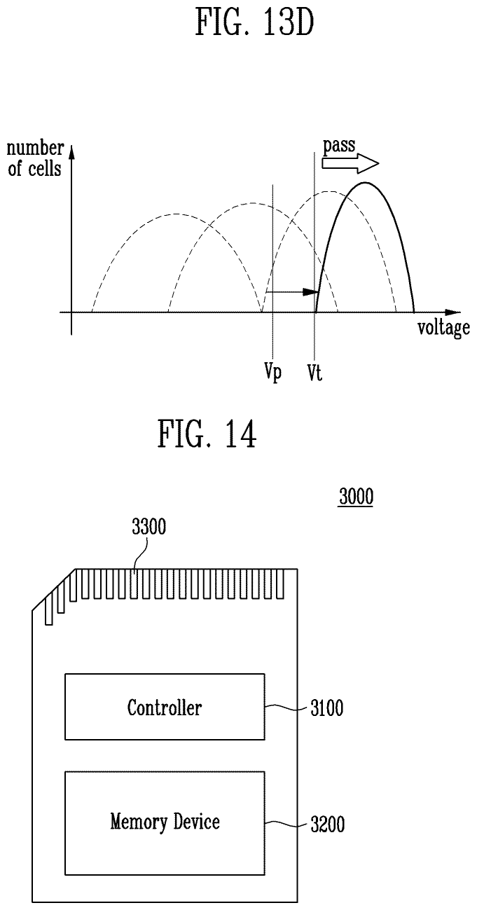

FIGS. 13A to 13D are diagrams illustrating the threshold voltages of memory cells that are successively increased during a program operation according to an embodiment of the present disclosure.

Referring to FIG. 13A, the program operation is performed on memory cells in an erase state, and thus the threshold voltages of memory cells, may be lower than a pre-target voltage Vp in an initial stage of the program operation. During a verify operation described above with reference to FIG. 5, a pre-verify operation and a target verify operation may be performed. Whether the program operation performed on a selected page has passed or failed may be determined depending on the result of the target verify operation. As shown in FIG. 13A, in the initial stage of the program operation, the threshold voltages of the memory cells may be less than a target voltage Vt, and thus the result of the verify operation may fail.

Because the result of verification fails, a voltage to be applied to bit lines connected to memory cells selected for a next program loop may be set. As shown in FIG. 13A, when the threshold voltages of the selected memory cells are less than the pre-target voltage Vp, the program-enable voltage may be applied to the bit lines connected to the selected memory cells.

Referring to FIG. 13B, when the threshold voltages of memory cells are increased by the program voltage, the selected page may include memory cells having threshold voltages greater than the target voltage Vt, memory cells having threshold voltages between the pre-target voltage Vp and the target voltage Vt, and memory cells having threshold voltages less than the pre-target voltage Vp. The reason why the memory cells programmed by the same program voltage have different threshold voltages is that the electrical characteristics of the memory cells are different from each other. That is, because the memory cells may be programmed at different speeds, the programmed memory cells cannot have the same threshold voltage. Therefore, the threshold voltages of memory cells corresponding to the same program state may be distributed within a range set to the same program state. As shown in FIG. 13B, when the number of memory cells having failed the verify operation is greater than the number of memory cells having passed the verify operation, the number of incomplete cells Nf may be greater than the reference number Nr.

In this case, in the next program loop, the program-enable voltage may be applied to bit lines of initial cells programmed having threshold voltages less than the pre-target voltage Vp, the second program-inhibit voltage and the program-enable voltage may be applied to bit lines of adjacent cells programmed having threshold voltages between the pre-target voltage Vp and the target voltage Vt at different times, and the first program-inhibit voltage may be applied to bit lines of complete cells programmed having threshold voltages higher than the target voltage Vt.

As shown in FIG. 13B, when the number of incomplete cells Nf is greater than the reference number Nr, the second program-inhibit voltage may be applied to the bit lines during a second time (e.g., CT2 of FIG. 11B or FIG. 12B).

Referring to FIG. 13C, when the threshold voltages of the memory cells are further increased due to the program voltage, the number of memory cells having passed the verify operation may become greater than the number of memory cells having failed the verify operation, and thus the number of incomplete cells Nf may be less than the reference number Nr.

In this case, in the next program loop, the program-enable voltage Val may be applied to bit lines of initial cells programmed MCi having threshold voltages less than the pre-target voltage Vp, the second program-inhibit voltage 2Vin and the program-enable voltage Val may be applied to bit lines of adjacent cells programmed having threshold voltages between the pre-target voltage Vp and the target voltage Vt at different times, and the first program-inhibit voltage 1Vin may be applied to bit lines of complete cells programmed MCc having threshold voltages greater than the target voltage Vt.

As shown in FIG. 13C, when the number of incomplete cells Nf is less than the reference number Nr, the second program-inhibit voltage 2Vin may be applied to the bit lines during a first time (e.g., CT1 of FIG. 11A or FIG. 12A).

Referring to FIG. 13D, when the threshold voltages of selected memory cells included in the selected page become greater than the target voltage Vt, the verify operation may pass, and the program operation on the selected page may be terminated.

FIG. 14 is a diagram illustrating a memory card system 3000 to which a memory device 100 according to an embodiment of the present disclosure is applied.

Referring to FIG. 14, the memory card system 3000 includes a controller 3100, a memory device 3200, and a connector 3300.

The controller 3100 is connected to the memory device 3200. The controller 3100 may access the memory device 3200. For example, the controller 3100 may control a program operation, a read operation, or an erase operation of the memory device 3200 or control background operations of the memory device 3200. The controller 3100 may provide an interface between the memory device 3200 and a host. The controller 3100 may run firmware for controlling the memory device 3200. For example, the controller 3100 may include components, such as a random access memory (RAM), a processor, a host interface, a memory interface, and an error correction circuit.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-e or PCIe), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include memory cells, and may be configured and operate in the same manner as the memory device 100 illustrated in FIG. 1. For example, the memory device 3200 may include memory cells, a peripheral circuit which programs the memory cells, and a control circuit which controls the peripheral circuit in response to a command. During a program operation, the peripheral circuit may perform a verify operation on the selected memory cells using a target voltage and a pre-target voltage lower than the target voltage. The control circuit may control the peripheral circuit to adjust the voltages to be applied to bit lines connected to the memory cells depending on the result of the verify operation, e.g., based on a classification of the memory cells as initial cells programmed MCi, adjacent cells programmed MCa, and complete cells programmed MCc. The control circuit may control the peripheral circuit to adjust the times during which corresponding voltages (e.g., Val, 2Vin, and 1Vin) are applied to the bit lines depending on the number of incomplete cells (e.g., number of initial cells programmed MCi and/or the number of adjacent cells programmed MCa) detected during the verify operation, as previously described.

The controller 3100 and the memory device 3200 may be integrated into a single semiconductor device to form a memory card. For example, the controller 3100 and the memory device 3200 may be integrated into a single semiconductor device and may then form a memory card such as a PC card (personal computer memory card international association: PCMCIA), a compact flash card (CF), a smart media card (SM or SMC), a memory stick, a multimedia card (MMC, RS-MMC, MMCmicro or eMMC), a secure digital (SD) card (SD, miniSD, microSD, or SDHC), universal flash storage (UFS), or the like.

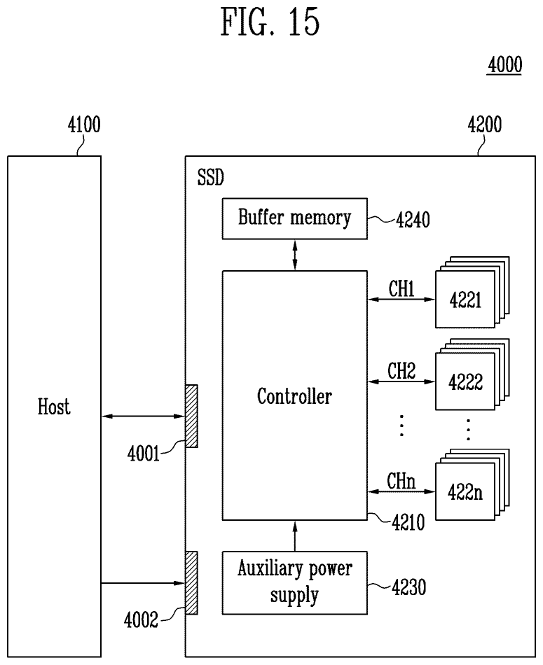

FIG. 15 is a diagram illustrating a solid state drive (SSD) system 4000 to which the memory device 100 according to an embodiment of the present disclosure is applied.

Referring to FIG. 15, the SSD system 4000 includes a host 4100 and an SSD 4200. The SSD 4200 may exchange signals with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the signals may be signals based on the interfaces of the host 4100 and the SSD 4200. For example, the signals may be signals defined by at least one of interfaces such as universal serial bus (USB), multimedia card (MMC), embedded MMC (eMMC), peripheral component interconnection (PCI), PCI-express (PCI-e or PCIe), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include cells in which data can be stored. Each of the plurality of memory devices 4221 to 422n may be configured in the same manner as the memory device 100 illustrated in FIG. 1. For example, each of the plurality of memory devices 4221 to 422n may include memory cells, a peripheral circuit which programs the memory cells, and a control circuit which controls the peripheral circuit in response to a command. During a program operation, the peripheral circuit may perform a verify operation on the selected memory cells using a target voltage and a pre-target voltage lower than the target voltage. The control circuit may control the peripheral circuit to adjust the voltages to be applied to bit lines connected to the memory cells depending on the result of the verify operation. The control circuit may control the peripheral circuit to adjust the times during which the corresponding voltages (e.g., Val, 2Vin, 1Vin) are applied to the bit lines depending on the number of incomplete cells (e.g., the number of initial cells programmed MCi and/or the number of adjacent cells programmed MCa) detected during the verify operation, as previously described.

The auxiliary power supply 4230 may be connected to the host 4100 through the power connector 4002. The auxiliary power supply 4230 may be supplied with power from the host 4100, and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board, and may provide auxiliary power to the SSD 4200.

The buffer memory 4240 functions as a buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

According to the present disclosure, the threshold voltage distributions of memory cells may be improved during a program operation, and thus the reliability of a memory device may be enhanced.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A memory device, comprising:
one or more memory cells;
a peripheral circuit configured to perform a program operation on the memory cells, verify the memory cells based on a target voltage and a pre-target voltage less than the target voltage, and apply bit line voltages to bit lines connected to the memory cells; and
a control circuit coupled to the peripheral circuit, and configured to:
determine the memory cells to initial cells programmed, adjacent cells programmed, and complete cells programmed depending on a result of a verification performed on the memory cells, and
adjust timings at which the bit line voltages are to be applied to the bit lines connected to the initial cells programmed, the adjacent cells programmed, and the complete cells programmed, wherein adjusting the timings of the bit line voltages includes controlling the peripheral circuit to adjust a timing of at least one bit line voltage to be applied to a bit line connected to one of the adjacent cells programmed, depending on a number of at least one of the initial cells programmed, the adjacent cells programmed, or the complete cells programmed.

2. The memory device according to claim 1, wherein the peripheral circuit is configured to selectively output a program-enable voltage, a second program-inhibit voltage, and a first program-inhibit voltage, as the bit line voltages to be applied to the bit lines, under control of the control circuit.

3. The memory device according to claim 2, wherein the second program-inhibit voltage is greater than the program-enable voltage and less than the first program-inhibit voltage.

4. The memory device according to claim 2, wherein the second program-inhibit voltage is greater than the program-enable voltage and equal to the first program-inhibit voltage.

5. The memory device according to claim 2, wherein the control circuit is configured to control the peripheral circuit to, while a program voltage is applied to a selected word line connected to the memory cells,
apply the program-enable voltage to a first bit line connected to the initial cells programmed, among the bit lines,
selectively apply the second program-inhibit voltage and the program-enable voltage to a second bit line connected to the adjacent cells programmed, among the bit lines, and
apply the first program-inhibit voltage to a third bit line connected to the complete cells programmed among the bit lines.

6. The memory device according to claim 5, wherein the peripheral circuit is configured to apply the second program-inhibit voltage to the second bit line during a first time and thereafter apply the program-enable voltage to the second bit line during a second time different from the first time.

7. The memory device according to claim 6, wherein the peripheral circuit is configured to control the peripheral circuit to:
apply the program-enable voltage to the first bit line and apply the first program-inhibit voltage to the third bit line during the first time, and
apply the program-enable voltage to the first bit line and apply the first program-inhibit voltage to the third bit line during the second time.

8. The memory device according to claim 5, wherein the peripheral circuit is configured to apply the program-enable voltage to the second bit line during the first time, and thereafter apply the second program-inhibit voltage to the second bit line during the second time.

9. The memory device according to claim 5, wherein the control circuit is configured to:
compare a number of incomplete cells, obtained based on the number of the initial cells programmed and the number of the adjacent cells programmed, with a reference number, and
control the peripheral circuit to adjust a time during which the second program-inhibit voltage is applied to the second bit line based on a result of the comparison.

10. The memory device according to claim 9, wherein the control circuit is configured to control the peripheral circuit to shorten the time during which the second program-inhibit voltage is applied to the second bit line when the number of incomplete cells is greater than the reference number.

11. The memory device according to claim 9, wherein the control circuit is configured to control the peripheral circuit to lengthen the time during which the second program-inhibit voltage is applied to the second bit line when the number of incomplete cells is greater than the reference number.

12. The memory device according to claim 9, wherein the control circuit is configured to control the peripheral circuit to lengthen the time during which the second program-inhibit voltage is applied to the second bit line when the number of incomplete cells is less than the reference number.

13. The memory device according to claim 9, wherein the control circuit is configured to control the peripheral circuit to shorten the time during which the second program-inhibit voltage is applied to the second bit line when the number of incomplete cells is less than the reference number.

14. The memory device according to claim 9, wherein the control circuit is configured to control the peripheral circuit to adjust a level of the second program-inhibit voltage to be applied to the second bit line depending on the result of the comparison.

15. A method of operating a memory device, comprising:
classifying memory cells as initial cells programmed, adjacent cells programmed, or complete cells programmed depending on a result of a verification performed on the memory cells during a program operation;
applying a program-enable voltage to a first bit line corresponding to the initial cells programmed, selectively applying a second program-inhibit voltage and the program-enable voltage to a second bit line corresponding to the adjacent cells programmed, and applying a first program-inhibit voltage to a third bit line corresponding to the complete cells programmed;
applying a program voltage to a word line connected to the memory cells; and adjusting a time during which the second program-inhibit voltage is applied to the second bit line depending on a number of initial cells programmed and the adjacent cells programmed.

16. The method according to claim 15, further comprising:
sequentially applying the second program-inhibit voltage and the program-enable voltage to the second bit line while the first program-inhibit voltage is applied to the third bit line.

17. The method according to claim 16, further comprising:
after the second program-inhibit voltage is applied to the second bit line, applying the program-enable voltage to the second bit line.

18. The method according to claim 16, further comprising:
after the program-enable voltage is applied to the second bit line, applying the second program-inhibit voltage to the second bit line.

19. The method according to claim 15, wherein the second program-inhibit voltage is greater than the program-enable voltage and less than the first program-inhibit voltage.

20. The method according to claim 15, wherein the second program-inhibit voltage is greater than the program-enable voltage and equal to the first program-inhibit voltage.

21. The method according to claim 15, wherein the time during which the second program-inhibit voltage is applied to the second bit line is adjusted depending on a result of comparing a number of the initial cells programmed and the adjacent cells programmed with a reference number.

22. The method according to claim 21, wherein the adjusting of the time during which the second program-inhibit voltage is applied includes shortening the time during which the second program-inhibit voltage is applied to the second bit line when the number of the initial cells programmed and the adjacent cells programmed is greater than the reference number.

23. The method according to claim 21, wherein the adjusting of the time during which the second program-inhibit voltage is applied includes, lengthening the time during which the second program-inhibit voltage is applied to the second bit line when the number of the initial cells programmed and the adjacent cells programmed is less than the reference number.
